(19) United States
(12) Patent Application Publication
(10) Pub. No.: US 2025/0252928 A1
(43) Pub. Date: Aug. 7, 2025

(54) DISPLAY DEVICE

(71) Applicant: LG Display Co., Ltd., Seoul (KR)

(72) Inventors: Booheung LEE, Gimpo-si (KR); HyeonJu TAK, Suwon-si (KR)

(21) Appl. No.: 18/967,130

(22) Filed: Dec. 3, 2024

(30) Foreign Application Priority Data
Feb. 5, 2024 (KR) 10-2024-0017705

(51) Int. Cl. G09G 3/3266; G09G 3/20; G09G 3/3233; G11C 19/28

(52) U.S. Cl. CPC G09G 3/3266; G09G 3/2092; G09G 3/3233; G09G 2300/0819; G09G 2300/0842; G09G 2300/0861; G09G 2310/0286; G09G 2310/08; G09G 2330/021; G11C 19/28

(57) ABSTRACT

A display device according to an example embodiment of the present disclosure includes a display panel including an active area in which a plurality of pixels is disposed and a non-active area which encloses the active area and a gate driver driven in any one of a first mode or a second mode to supply a gate signal to the plurality of pixels, the gate driver includes a plurality of stages and a mode controller connected between the plurality of stages to control an operation of the gate driver according to a mode control signal.

### CROSS-REFERENCE TO RELATED APPLICATIONS

This application claims the priority of Korean Patent Application No. 10-2024-0017705 filed on Feb. 5, 2024, in the Korean Intellectual Property Office, the disclosure of which is incorporated herein by reference.

### BACKGROUND

### Technical Field

The present disclosure relates to a display device, and more particularly, to a display device which is driven with a low power without lowering a frequency.

### Description of the Related Art

As technology in modern society develops, display devices are used in various ways to provide information to users. The display devices include not only electronic signs which simply transmit visual information in one direction, but also various electronic devices which require higher level of technology to check user's input and provide information in response to the checked input.

A representative display device may include a liquid crystal display device (LCD), a field emission display device (FED), an electro-wetting display device (EWD), and an organic light emitting display device (OLED).

Among them, the organic light emitting display device is a self-emitting display device so that a separate light source is not necessary, which is different from the liquid crystal display device. Therefore, the organic light emitting display device may be manufactured to have a light weight and a small thickness. Further, since the organic light emitting display device is advantageous not only in terms of power consumption due to the low voltage driving, but also in terms of color implementation, a response speed, a viewing angle, and a contrast ratio (CR), it is expected to be utilized in various fields.

### BRIEF SUMMARY

The present disclosure provides a display device which is driven with a low power without lowering a frequency.

The present disclosure provides a display device in which an overall display panel is driven at a high speed during a divisional operation and also changes a resolution for every divided area of the display panel.

The present disclosure provides a display device which ensures a sufficient sampling time of pixels even in a high resolution and a high speed operation.

Technical features of the present disclosure are not limited to the above-mentioned objects, and other objects, which are not mentioned above, can be clearly understood by those skilled in the art from the following descriptions.

A display device according to an example embodiment of the present disclosure includes a display panel including an active area in which a plurality of pixels is disposed and a non-active area which encloses the active area and a gate driver which is driven in any one of a first mode or a second mode to supply a gate signal to the plurality of pixels, the gate driver includes a plurality of stages and a mode controller which is connected between the plurality of stages to control an operation of the gate driver according to a mode control signal.

Other detailed matters of the example embodiments are included in the detailed description and the drawings.

According to the present disclosure, the display device is driven with a low resolution without lowering the frequency to be driven with a low power so that the power consumption is reduced.

According to the present disclosure, during the divisional operation, the entire display panel is driven at a high speed and the resolution is changed for every divided area of the display panel to respond to various contents.

According to the present disclosure, a data voltage is supplied to pixels through two data lines so that a sufficient sampling time of pixels may be ensured even in a high resolution and the high speed operation.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a functional block diagram of a display device according to an example embodiment of the present disclosure;

FIG. 2 is a schematic view for explaining an active area of a display device according to an example embodiment of the present disclosure;

FIG. 3 is an example circuit diagram of a pixel circuit of a display device according to an example embodiment of the present disclosure;

FIG. 4 is a functional block diagram of a gate driver of a display device according to an example embodiment of the present disclosure;

FIG. 5 is an example circuit diagram of a shift register circuit of a display device according to an example embodiment of the present disclosure;

FIG. 6 is an example circuit diagram of an edge trigger circuit of a display device according to an example embodiment of the present disclosure;

FIG. 7 is a schematic diagram of a gate driver to which a shift register circuit is applied, among gate drivers of a display device according to an example embodiment of the present disclosure;

FIG. 8 is a waveform diagram illustrating various signals in a first mode operation of a gate driver of FIG. 7;

FIG. 9 is a schematic diagram for explaining a first mode operation of a gate driver of FIG. 7;

FIG. 10 is a waveform diagram illustrating various signals in a second mode operation of a gate driver of FIG. 7;

FIG. 11 is a schematic diagram for explaining a second mode operation of a gate driver of FIG. 7;

FIG. 12 is a schematic diagram of a gate driver to which an edge trigger circuit is applied, among gate drivers of a display device according to an example embodiment of the present disclosure;

FIG. 13 is a waveform diagram illustrating various signals in a first mode operation of a gate driver of FIG. 12;

FIG. 14 is a schematic diagram for explaining a first mode operation of a gate driver of FIG. 12;

FIG. 15 is a waveform diagram illustrating various signals in a second mode operation of a gate driver of FIG. 12;

FIG. 16 is a schematic diagram for explaining a second mode operation of a gate driver of FIG. 12;

FIG. 17 is a schematic view for explaining an active area of a display device according to another example embodiment of the present disclosure;

FIG. 18 is a functional block diagram of a gate driver of a display device according to another example embodiment of the present disclosure;

FIG. 19 is a schematic diagram of a gate driver to which a shift register circuit is applied, among gate drivers of a display device according to another example embodiment of the present disclosure;

FIG. 20 is a waveform diagram illustrating various signals in a first mode operation of a gate driver of FIG. 19;

FIG. 21 is a schematic diagram for explaining a first mode operation of a gate driver of FIG. 19;

FIG. 22 is a waveform diagram illustrating various signals in a second mode operation of a gate driver of FIG. 19;

FIG. 23 is a schematic diagram for explaining a second mode operation of a gate driver of FIG. 19;

FIG. 24 is a schematic diagram of a gate driver to which an edge trigger circuit is applied, among gate drivers of a display device according to another example embodiment of the present disclosure;

FIG. 25 is a waveform diagram illustrating various signals in a first mode operation of a gate driver of FIG. 24;

FIG. 26 is a schematic diagram for explaining a first mode operation of a gate driver of FIG. 24;

FIG. 27 is a waveform diagram illustrating various signals in a second mode operation of a gate driver of FIG. 24; and

FIG. 28 is a schematic diagram for explaining a second mode operation of a gate driver of FIG. 24.

### DETAILED DESCRIPTION

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

In describing components of the example embodiment of the present disclosure, terminologies such as first, second, A, B, (a), (b), and the like may be used. These terminologies are used to distinguish a component from the other component, but a nature, an order, or the number of the components is not limited by the terminology. When a component is “linked,” “coupled,” or “connected” to another component, the component may be directly linked or connected to the other component. However, unless specifically stated otherwise, it should be understood that a third component may be interposed between the components which may be indirectly linked or connected.

When the position relation between two parts is described using the terms such as “on,” “above,” “below,” and “next,” one or more parts may be positioned between the two parts unless the terms are used with the term “immediately” or “directly.”

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

The features of various embodiments of the present disclosure can be partially or entirely adhered to or combined with each other and can be interlocked and operated in technically various ways, and the embodiments can be carried out independently of or in association with each other.

The following embodiments will be described focusing on the organic light emitting display device. However, embodiments of the present specification are not limited to organic light emitting display devices and can be applied to various electroluminescent displays. For example, the electroluminescent display apparatus may use an organic light emitting diode (OLED) display apparatus, a quantum dot light emitting diode display apparatus, or an inorganic light emitting diode display apparatus.

Hereinafter, example embodiments of the present disclosure will be described in detail with reference to accompanying drawings.

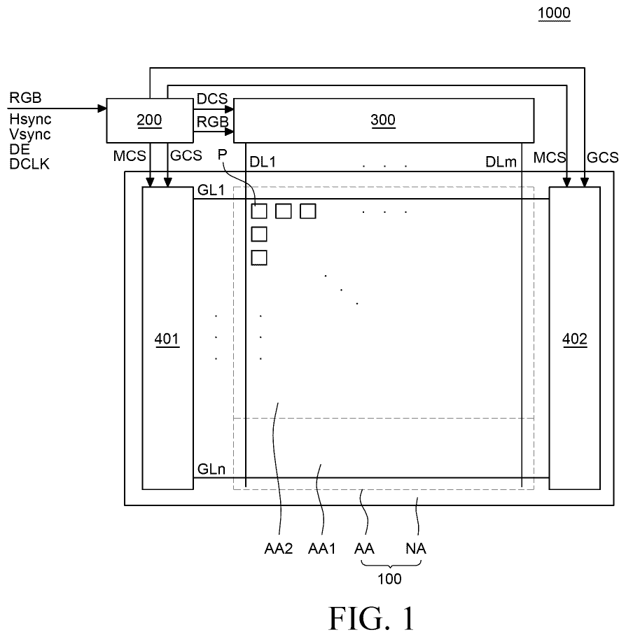

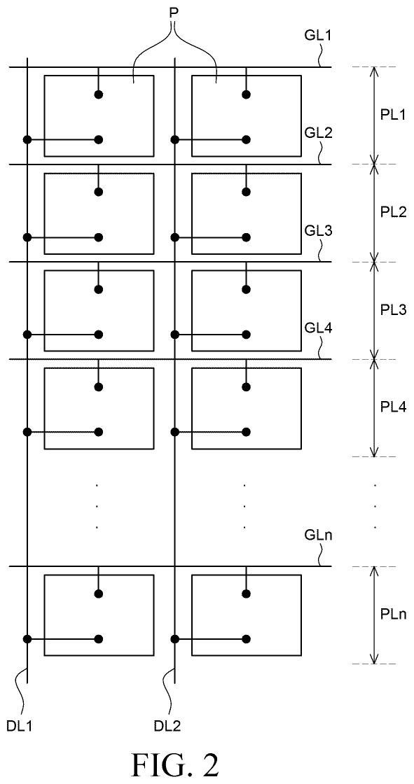

FIG. 1 is a functional block diagram of a display device according to an example embodiment of the present disclosure. FIG. 2 is a schematic view for explaining an active area of a display device according to an example embodiment of the present disclosure.

Referring to FIGS. 1 and 2, a display device 1000 according to the example embodiment of the present disclosure includes a display panel 100, a timing controller 200, a data driver 300, and gate drivers 401 and 402.

The display panel 100 includes an active area AA in which an image is displayed and a non-active area NA which is disposed at the outside of the active area AA. Various signal lines and the gate drivers 401 and 402 are disposed in the non-active area NA.

In the active area AA, a plurality of pixels P is disposed to display images.

In the active area AA, a plurality of gate lines GL1 to GLn disposed in a first direction and a plurality of data lines DL1 to DLm disposed in a second direction which is different from the first direction are disposed. The plurality of gate lines GL1 to GLn and the plurality of data lines DL1 to DLm may intersect and the plurality of pixels P may be disposed in a matrix (n and m are integers of 1 or larger) form.

The plurality of pixels P is electrically connected to the plurality of gate lines GL1 to GLn and the plurality of data lines DL1 to DLm. Accordingly, gate voltages and data voltages are applied to the pixels P through the gate lines GL1 to GLn and the data lines DL1 to DLm, respectively. Each pixel P implements a gray scale by the gate voltage and the data voltage to display the image in the active area AA.

Each of the plurality of pixels P may be any one of a red pixel, a green pixel, a blue pixel, and a white pixel. The red pixel, the green pixel, the blue pixel, and the white pixel may configure one unit pixel to implement colors. Colors implemented in the unit pixel may be determined according to an emission ratio of the red pixel, the green pixel, the blue pixel, and the white pixel. In the meantime, the white pixel may be omitted in the unit pixel. Each of the plurality of pixels P is connected to one of data line DL1 to DLm and one of gate line GL1 to GLn.

In the active area AA, a plurality of pixel lines PL1 to PL4 is provided and a plurality of pixels P which is adjacent to each other in a row direction to be commonly connected to each of the gate lines GL1 to GLn is disposed on each of the pixel lines PL1 to PL4. Here, the pixel lines PL1 to PL4 may be a set of pixels corresponding to one line connected to one gate line GL1 to GLn disposed in the row direction.

The active area AA may be divided in a plurality of areas as needed. For example, when the screen is driven with two driving screens, the active area AA is divided into a first active area AA1 and a second active area AA2 in a column direction to be driven and the first active area AA1 and the second active area AA2 are individually driven with different resolutions. An area and a position of the first active area AA1 and the second active area AA2 which are divided to be driven are not limited and may vary according to an image which is displayed through the active area AA. In the non-active area NA, various signal lines, such as gate lines GL1 to GLn and data lines DL1 to DLm which transmit signals to control the operation of the pixels P disposed in the active area AA and the gate drivers 401 and 402 are disposed.

The timing controller 200 transmits an input image signal RGB received from a host system to the data driver 300.

The timing controller 200 generates control signals GCS and DCS for controlling operation timings of the gate drivers 401 and 402 and the data driver 300 using timing signals, such as a clock signal DCLK, a horizontal synchronization signal Hsync, a vertical synchronization signal Vsync, and a data enable signal DE. The timing signals are received together with the image data RGB. Here, the horizontal synchronization signal Hsync is a signal representing a time taken to display one horizontal line of a screen and the vertical synchronization signal Vsync is a signal representing a time taken to display a screen of one frame. The data enabler signal DE is a signal representing a period when a data voltage is supplied to a pixel P defined in the display panel 100.

In other words, the timing controller 200 is applied with the timing signal to output a gate control signal GCS to the gate drivers 401 and 402 and output a data control signal DCS to the data driver 300.

The timing controller 200 outputs a mode control signal MCS which controls a driving mode of the gate drivers 401 and 402 to the gate drivers 401 and 402 using a mode control signal received from the host system. Here, the mode control signal MCS is a signal which enables divisional operation for every area of the display panel 100 and controls a driving mode of the gate drivers 401 and 402 when the resolution of each area varies. For example, the mode control signal MCS includes a first mode control signal MCS1 and a second mode control signal MCS2. For example, the first mode control signal MCS1 is a signal which controls the gate drivers 401 and 402 to operate in a high resolution mode when the corresponding area of the display panel 100 is driven with a high resolution. The second mode control signal MCS2 is a signal which controls the gate drivers 401 and 402 to operate in a low resolution mode when the corresponding area of the display panel 100 is driven with a low resolution.

The data driver 300 is applied with the data control signal DCS to output a data voltage to the data lines DL1 to DLm.

Specifically, the data driver 300 generates a sampling signal in accordance with the data control signal DCS and latches the image data RGB in accordance with the sampling signal to be converted into a data voltage and then supplies the data voltage to the data line DL1 to DLm in response to a source output enable (SOE) signal.

The data driver 300 is connected to a bonding pad of the display panel 100 in a chip on glass (COG) manner or may be directly disposed on the display panel 100. In some cases, the data driver 300 may be disposed to be integrated with the display panel 100. Further, the data driver 300 may be disposed in a chip on film (COF) manner.

The gate drivers 401 and 402 sequentially supply a scan signal and an emission signal corresponding to the gate signal to the gate lines GL1 to GLn, in accordance with the gate control signal GCS.

The general gate drivers 401 and 402 are formed independently from the display panel 100 to be electrically connected to the display panel 100 in various ways. However, the gate drivers 401 and 402 of the display device according to the example embodiment of the present disclosure are formed to have a thin film pattern when a substrate of the display panel 100 is manufactured to be embedded on the non-active area NA in a gate in panel (GIP) manner. The gate drivers 401 and 402 may be a first gate driver 401 and a second gate driver 402 which are disposed on both sides of the display panel 100. However, the present disclosure is not limited thereto and the gate drivers 401 and 402 are disposed on only one side of the display panel 100.

Each of the gate drivers 401 and 402 includes a plurality of scan driving stages which outputs a plurality of scan signals to the plurality of pixels P and a plurality of emission driving stages which outputs a plurality of emission signals to the plurality of pixels P.

Hereinafter, a configuration of the plurality of pixels P will be described in detail.

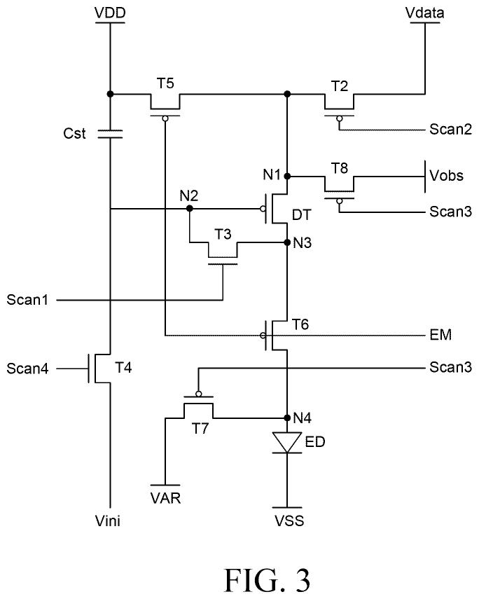

FIG. 3 is an example circuit diagram of a pixel circuit of a display device according to an example embodiment of the present disclosure.

Referring to FIG. 3, a circuit of the pixel P includes a light emitting diode ED, a driving transistor DT, a second transistor T2, a third transistor T3, a fourth transistor T4, a fifth transistor T5, a sixth transistor T6, a seventh transistor T7, an eighth transistor T8, and a storage capacitor Cst.

The light emitting diode ED emits light by a driving current supplied from the driving transistor DT. An anode electrode of the light emitting diode ED is connected to a fourth node N4 and a cathode electrode is connected to a low potential power line to which a low potential power voltage VSS is supplied.

The driving transistor DT controls a driving current applied to the light emitting diode ED in accordance with a source-gate voltage Vsg. The driving transistor DT may be a p-type MOSFET (PMOS) and may be implemented by a low temperature polycrystalline silicon (LTPS) thin film transistor. A source electrode of the driving transistor DT is connected to a first node N1, a gate electrode is connected to a second node N2, and a drain electrode is connected to a third node N3. The driving transistor DT may be referred to as a first transistor.

The second transistor T2 applies a data voltage Vdata supplied from the data line to the first node N1 which is the source electrode of the driving transistor DT. The second transistor T2 may be a p-type MOSFET (PMOS) and may be implemented by a low temperature polycrystalline silicon (LTPS) thin film transistor. The second transistor T2 includes a source electrode connected to the data line, a drain electrode connected to the first node N1, and a gate electrode connected to a second scan signal line which transmits a second scan signal Scan2. Accordingly, the second transistor T2 applies a data voltage Vdata supplied from the data line to the first node N1 which is the source electrode of the driving transistor DT, in response to a low level of second scan signal Scan2 which is a turn-on voltage.

The third transistor T3 diode-connects the gate electrode and the drain electrode of the driving transistor DT. The third transistor T3 may be an n-type MOSFET (NMOS) and may be implemented by an oxide thin film transistor to reduce a leakage current during a turn-off period. The third transistor T3 includes a drain electrode or a source electrode connected to the third node N3, a source electrode or a drain electrode connected to the second node N2, and a gate electrode connected to a first scan signal line which transmits a first scan signal Scan1. Therefore, the third transistor T3 diode-connects the gate electrode and the drain electrode of the driving transistor DT in response to a high level of first scan signal Scan1 which is a turn-on voltage.

The fourth transistor T4 applies an initialization signal Vini to the second node N2 which is the gate electrode of the driving transistor DT. The fourth transistor T4 may be an n-type MOSFET (NMOS) and may be implemented by an oxide thin film transistor. The fourth transistor T4 includes a source electrode connected to an initialization signal line which transmits an initialization signal Vini, a drain electrode connected to the second node N2, and a gate electrode connected to a fourth scan signal line which transmits a fourth scan signal Scan4. Accordingly, the fourth transistor T4 applies the initialization signal Vini to the second node N2 which is the gate electrode of the driving transistor DT, in response to a high level of fourth scan signal Scan4 which is a turn-on voltage.

The fifth transistor T5 applies a high potential power voltage VDD to the first node N1 which is the source electrode of the driving transistor DT. The fifth transistor T5 may be a p-type MOSFET (PMOS) and may be implemented by a low temperature polycrystalline silicon (LTPS) thin film transistor. The fifth transistor T5 includes a source electrode connected to a high potential driving voltage line which transmits a high potential power voltage VDD, a drain electrode connected to the first node N1, and a gate electrode connected to an emission signal line which transmits an emission signal EM(n). Accordingly, the fifth transistor T5 applies the high potential power voltage VDD to the first node N1 which is the source electrode of the driving transistor DT, in response to a low level of emission signal EM(n) which is a turn-on voltage.

The sixth transistor T6 forms a current path between the driving transistor DT and the light emitting diode ED. The sixth transistor T6 may be a p-type MOSFET (PMOS) and may be implemented by a low temperature polycrystalline silicon (LTPS) thin film transistor. The sixth transistor T6 includes a source electrode connected to the third node N3, a drain electrode connected to the fourth node N4, and a gate electrode connected to the emission signal line which transmits an emission signal EM(n). The sixth transistor T6 forms a current path between the third node N3 which is the source electrode of the sixth transistor T6 and the fourth node N4 which is the drain electrode of the sixth transistor T6, in response to the emission signal EM(n). Accordingly, the sixth transistor T6 forms a current path between the driving transistor DT and the light emitting diode ED in response to a low level of emission signal EM(n) which is a turn-on voltage.

The seventh transistor T7 applies a reset voltage VAR to the fourth node N4 which is an anode of the light emitting diode ED. The seventh transistor T7 may be a p-type MOSFET (PMOS) and may be implemented by a low temperature polycrystalline silicon (LTPS) thin film transistor. The seventh transistor T7 includes a source electrode connected to a reset voltage line which transmits a reset voltage VAR, a drain electrode connected to the fourth node N4, and a gate electrode connected to a third scan signal line which transmits a third scan signal Scan3. Accordingly, the seventh transistor T7 applies the reset voltage VAR to the fourth node N4 which is the anode of the light emitting diode ED, in response to a low level of third scan signal Scan3 which is a turn-on level.

The eighth transistor T8 applies an on-bias stress voltage Vobs to the first node N1 which is the source electrode of the driving transistor DT. The eighth transistor T8 may be a p-type MOSFET (PMOS) and may be implemented by a low temperature polycrystalline silicon (LTPS) thin film transistor. The eighth transistor T8 includes a source electrode connected to an on-bias stress voltage line which transmits an on-bias stress voltage Vobs, a drain electrode connected to the first node N1, and a gate electrode connected to a third scan signal line which transmits a third scan signal Scan3. Accordingly, the eighth transistor T8 applies the on-bias stress voltage Vobs to the first node N1 which is the source electrode of the driving transistor DT, in response to a low level of third scan signal Scan3 which is a turn-on level.

The storage capacitor Cst maintains a data voltage Vdata stored in each sub pixel for one frame. The storage capacitor Cst includes a first electrode connected to the second node N2 and a second electrode connected to the high potential power voltage line which transmits a high potential power voltage VDD. That is, one electrode of the storage capacitor Cst is connected to the gate electrode of the driving transistor DT and the other electrode of the storage capacitor Cst is connected to the high potential power line which transmits the high potential power voltage VDD. Hereinafter, the gate drivers 401 and 402 will be described in more detail.

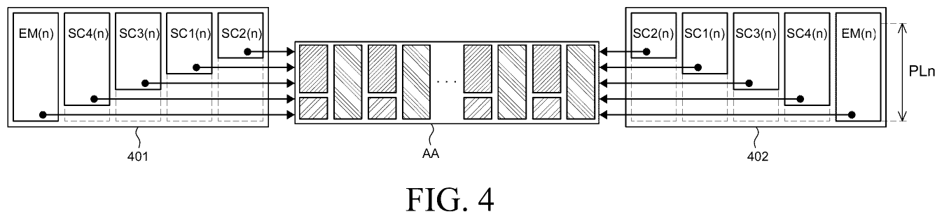

FIG. 4 is a functional block diagram of a gate driver of a display device according to an example embodiment of the present disclosure. In FIG. 4, for the convenience of description, only gate drivers 401 and 402 for one pixel line Ln are illustrated.

Referring to FIG. 4, the gate drivers 401 and 402 are disposed symmetrically in the non-active areas NA on both sides of the active area AA to supply scan signals Scan1 to Scan4 to the plurality of pixels P and supply the emission signal EM(n) to the plurality of pixels P.

Each of the gate drivers 401 and 402 includes a first scan driver SC1(n), a second scan driver SC2(n), a third scan driver SC3(n), a fourth scan driver SC4(n), and an emission driver EM(n). Each of the first scan driver SC1(n), the second scan driver SC2(n), the third scan driver SC3(n), the fourth scan driver SC4(n), and the emission driver EM(n) includes a plurality of stages.

In each of the gate drivers 401 and 402, the second scan driver SC2(n), the first scan driver SC1(n), the third scan driver SC3(n), the fourth scan driver SC4(n), and the emission driver EM(n) are disposed in this order from a position adjacent to the active area AA. However, it is not limited thereto and it may be changed depending on the design.

The first scan driver SC1(n) outputs a first scan signal Scan1 in response to the gate control signal GDC from the timing controller 200 and the second scan driver SC2(n) outputs a second scan signal Scan2 in response to the gate control signal GDC from the timing controller 200. The third scan driver SC3(n) outputs a third scan signal Scan3 in response to the gate control signal GDC from the timing controller 200 and the fourth scan driver SC4(n) outputs a fourth scan signal Scan4 in response to the gate control signal GDC from the timing controller 200. The emission driver EM(n) outputs an emission signal EM in response to the gate control signal GDC from the timing controller 200.

One scan driver of the first scan driver SC1(n), the second scan driver SC2(n), the third scan driver SC3(n), and the fourth scan driver SC4(n) is configured by a shift register circuit and the remaining scan drivers and the emission driver EM(n) are configured by edge trigger circuits. For example, each of the plurality of stages included in the second scan driver SC2(n) is configured by a shift register circuit and each of the plurality of stages included in the first scan driver SC1(n), the third scan driver SC3(n), the fourth scan driver SC4(n), and the emission driver EM(n) is configured by an edge trigger circuit.

Hereinafter, the shift register circuit and the edge trigger circuit will be described in detail.

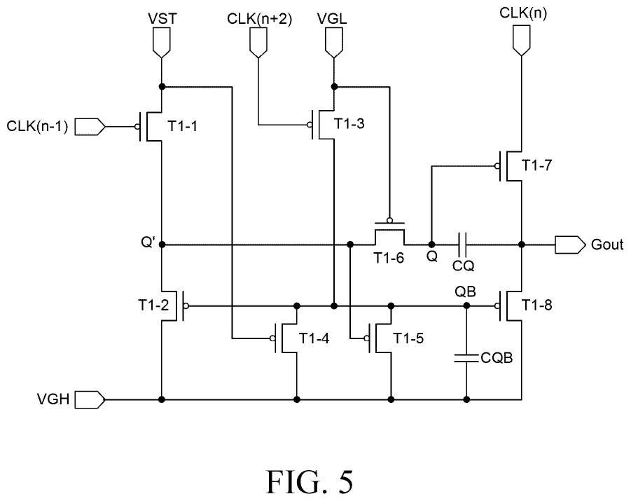

FIG. 5 is an example circuit diagram of a shift register circuit of a display device according to an example embodiment of the present disclosure.

Referring to FIG. 5, the shift register circuit includes a 1-1-th transistor T1-1, a 1-2-th transistor T1-2, a 1-3-th transistor T1-3, a 1-4-th transistor T1-4, a 1-5-th transistor T1-5, a 1-6-th transistor T1-6, a 1-7-th transistor T1-7, an 1-8-th transistor T1-8, a 1-1-th capacitor CQ, and a 1-2-th capacitor CQB.

The 1-1-th transistor T1-1 is connected between a line which supplies a start signal VST and a Q′ node Q′. For example, a source electrode of the 1-1-th transistor T1-1 is connected to a line which supplies a start signal VST and a drain electrode is connected to the Q′ node Q′. Further, a gate electrode of the 1-1-th transistor T1-1 is connected to a line to which a clock signal CLK (n-1) of a n-1-th stage is applied. The 1-1-th transistor T1-1 may be a p-type MOSFET (PMOS) and may be implemented by a low temperature polycrystalline silicon (LTPS) thin film transistor. Therefore, the 1-1-th transistor T1-1 applies the start signal VST to the Q′ node Q′ in response to a low level of clock signal CLK (n-1) which is a turn-on voltage. The 1-2-th transistor T1-2 is connected between a line which supplies a gate high voltage VGH and the Q′ node Q′. For example, a source electrode of the 1-2-th transistor T1-2 is connected to the line which supplies the gate high voltage VGH and a drain electrode is connected to the Q′ node Q′. Further, the gate electrode of the 1-2-th transistor T1-2 is connected to the QB node QB. The 1-2-th transistor T1-2 may be a p-type MOSFET (PMOS) and may be implemented by a low temperature polycrystalline silicon (LTPS) thin film transistor. Therefore, when a voltage of the QB node QB is a low level voltage which is a turn-on voltage, the 1-2-th transistor T1-2 applies the gate high voltage VGH to the Q′ node Q′.

The 1-3-th transistor T1-3 is connected between a line which supplies a gate low voltage VGL and the QB node QB. For example, a source electrode of the 1-3-th transistor T1-3 is connected to the line which supplies the gate high voltage VGH and a drain electrode is connected to the QB node QB. Further, a gate electrode of the 1-3-th transistor T1-3 is connected to a line to which a clock signal CLK (n+2) of a n+2-th stage is applied. The 1-3-th transistor T1-3 may be a p-type MOSFET (PMOS) and may be implemented by a low temperature polycrystalline silicon (LTPS) thin film transistor. Therefore, when the clock signal CLK (n+2) of the n+2-th stage is a low level which is a turn-on voltage, the 1-3-th transistor T1-3 applies the gate low voltage VGL to the QB node QB.

The 1-4-th transistor T1-4 is connected between a line which supplies a gate high voltage VGH and the QB node QB. For example, a source electrode of the 1-4-th transistor T1-4 is connected to the line which supplies the gate high voltage VGH and a drain electrode is connected to the QB node QB. Further, a gate electrode of the 1-4-th transistor T1-4 is connected to the line which supplies the start signal VST. The 1-4-th transistor T1-4 may be a p-type MOSFET (PMOS) and may be implemented by a low temperature polycrystalline silicon (LTPS) thin film transistor. Therefore, when the start signal VST is a low level which is a turn-on voltage, the 1-4-th transistor T1-4 applies the gate high voltage VGH to the QB node QB.

The 1-5-th transistor T1-5 is connected between the line which supplies a gate high voltage VGH and the QB node QB. For example, a source electrode of the 1-5-th transistor T1-5 is connected to the line which supplies the gate high voltage VGH and a drain electrode is connected to the QB node QB. Further, a gate electrode of the 1-5-th transistor T1-5 is connected to the Q′ node Q′. The 1-5-th transistor T1-5 may be a p-type MOSFET (PMOS) and may be implemented by a low temperature polycrystalline silicon (LTPS) thin film transistor. Therefore, when a voltage applied to the Q′ node Q′ is a low level, the 1-5-th transistor T1-5 applies the gate high voltage VGH to the QB node QB.

The 1-6-th transistor T1-6 is connected between the Q′ node Q′ and the Q node Q. For example, a source electrode of the 1-6-th transistor T1-6 is connected to the Q′ node Q′ and a drain electrode is connected to the Q node Q. Further, a gate electrode of the 1-6-th transistor T1-6 is connected to the line which supplies the gate low voltage VGL. The 1-6-th transistor T1-6 may be a p-type MOSFET (PMOS) and may be implemented by a low temperature polycrystalline silicon (LTPS) thin film transistor. Therefore, the 1-6-th transistor T1-6 is maintained in a turned-on state by the gate low voltage VGL to apply a voltage which is applied to the Q′ node Q′ to the Q node Q.

The 1-7-th transistor T1-7 is connected between a line to which a clock signal CLK (n) of an n-th stage is applied and an output terminal Gout. For example, a source electrode of the 1-7-th transistor T1-7 is connected to the line to which a clock signal CLK (n) of an n-th stage is applied and a drain electrode is connected to the output terminal Gout. Further, a gate electrode of the 1-7-th transistor T1-7 is connected to the Q node Q. The 1-7-th transistor T1-7 may be a p-type MOSFET (PMOS) and may be implemented by a low temperature polycrystalline silicon (LTPS) thin film transistor. Therefore, when the voltage applied to the Q node Q is a low level which is a turn-on voltage, the 1-7-th transistor T1-7 outputs a clock signal CLK (n) of the n-th stage to the output terminal Gout.

The 1-8-th transistor T1-8 is connected between the line which supplies a gate high voltage VGH and the output terminal Gout. For example, a source electrode of the 1-8-th transistor T1-8 is connected to the line which supplies the gate high voltage VGH and a drain electrode is connected to the output terminal Gout. Further, the gate electrode of the 1-8-th transistor T1-8 is connected to the QB node QB. The 1-8-th transistor T1-8 may be a p-type MOSFET (PMOS) and may be implemented by a low temperature polycrystalline silicon (LTPS) thin film transistor. Therefore, when a voltage applied to the QB node QB is a low level which is a turn-on voltage, the 1-8-th transistor T1-8 applies the gate high voltage VGH to the output terminal Gout.

The 1-1-th capacitor CQ is connected between the Q node Q and the output terminal Gout. For example, a first electrode of the 1-1-th capacitor CQ is connected to the Q node Q and a second electrode is connected to the output terminal Gout. Therefore, the 1-1-th capacitor CQ may store a voltage applied to the Q node Q.

The 1-2-th capacitor CQB is connected between the QB node QB and the line which supplies a gate high voltage VGH. For example, the first electrode of the 1-2-th capacitor CQB is connected to the QB node QB and the second electrode is connected to the line which supplies the gate high voltage VGH. Therefore, the 1-2-th capacitor CQB may store a voltage applied to the QB node QB.

Hereinafter, the shift register circuit and the edge trigger circuit will be described in detail.

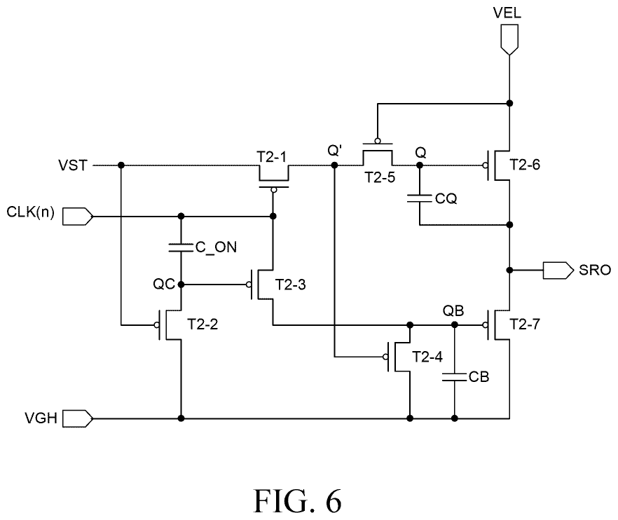

FIG. 6 is an example circuit diagram of an edge trigger circuit of a display device according to an example embodiment of the present disclosure.

Referring to FIG. 6, the edge trigger circuit includes a 2-1-th transistor T2-1, a 2-2-th transistor T2-2, a 2-3-th transistor T2-3, a 2-4-th transistor T2-4, a 2-5-th transistor T2-5, a 2-6-th transistor T2-6, a 2-7-th transistor T2-7, a 2-1-th capacitor C_ON, a 2-2th capacitor CQ, and a 2-3-th capacitor CQB.

The 2-1-th transistor T2-1 is connected between a line which supplies a start signal VST and a Q′ node Q′. For example, a source electrode of the 2-1-th transistor T2-1 is connected to a line which supplies a start signal VST and a drain electrode is connected to the Q′ node Q′. Further, a gate electrode of the 2-1-th transistor T2-1 is connected to a line to which a clock signal CLK (n) of a n-th stage is applied. The 2-1-th transistor T2-1 may be a p-type MOSFET (PMOS) and may be implemented by a low temperature polycrystalline silicon (LTPS) thin film transistor. Therefore, the 2-1-th transistor T2-1 applies the start signal VST to the Q′ node Q′ in response to a low level of clock signal CLK (n) which is a turn-on voltage.

The 2-2-th transistor T2-2 is connected between a line which supplies a gate high voltage VGH and the QC node QC. For example, a source electrode of the 2-2-th transistor T2-2 is connected to the line which supplies the gate high voltage VGH and a drain electrode is connected to the QC node QC. Further, a gate electrode of the 2-2-th transistor T2-2 is connected to a line which supplies the start signal VST. The 2-2-th transistor T2-2 may be a p-type MOSFET (PMOS) and may be implemented by a low temperature polycrystalline silicon (LTPS) thin film transistor. Therefore, when a start signal VST is a low level which is a turn-on voltage, the 2-2-th transistor T2-2 applies the gate high voltage VGH to the QC node QC.

The 2-3-th transistor T2-3 is connected between a line to which a clock signal CLK (n) of an n-th stage is applied and the QB node QB. For example, a source electrode of the 2-3-th transistor T2-3 is connected to the line to which a clock signal CLK (n) of an n-th stage is applied and a drain electrode is connected to the QB node QB. Further, a gate electrode of the 2-3-th transistor T2-3 is connected to the QC node QC. The 2-3-th transistor T2-3 may be a p-type MOSFET (PMOS) and may be implemented by a low temperature polycrystalline silicon (LTPS) thin film transistor. Therefore, when a voltage of the QC node QC is a low level voltage which is a turn-on voltage, the 2-3-th transistor T2-3 applies the clock signal CLK (n) to the QB node QB.

The 2-4-th transistor T2-4 is connected between the line which supplies the gate high voltage VGH and the QB node QB. For example, a source electrode of the 2-4-th transistor T2-4 is connected to the line which supplies the gate high voltage VGH and a drain electrode is connected to the QB node QB. Further, a gate electrode of the 2-4-th transistor T2-4 is connected to the Q′ node Q′. The 2-4-th transistor T2-4 may be a p-type MOSFET (PMOS) and may be implemented by a low temperature polycrystalline silicon (LTPS) thin film transistor. Therefore, when a voltage applied to the Q′ node Q′ is a low level, the 2-4-th transistor T2-4 applies the gate high voltage VGH to the QB node QB.

The 2-5-th transistor T2-5 is connected between the Q′ node Q′ and the Q node Q. For example, a source electrode of the 2-5-th transistor T2-5 is connected to the Q′ node Q′ and a drain electrode is connected to the Q node Q. Further, a gate electrode of the 2-5-th transistor T2-5 is connected to a line which supplies the gate low voltage VGL. The 2-5-th transistor T2-5 may be a p-type MOSFET (PMOS) and may be implemented by a low temperature polycrystalline silicon (LTPS) thin film transistor. Therefore, the 2-5-th transistor T2-5 is maintained in a turned-on state by the gate low voltage VGL to apply a voltage which is applied to the Q′ node Q′ to the Q node Q.

The 2-6-th transistor T2-6 is connected between the line which supplies the gate low voltage VGL and the output terminal Gout. For example, a source electrode of the 2-6-th transistor T2-6 is connected to the line which supplies the gate low voltage VGL and a drain electrode is connected to the output terminal Gout. Further, a gate electrode of the 2-6-th transistor T2-6 is connected to the Q node Q. The 2-6-th transistor T2-6 may be a p-type MOSFET (PMOS) and may be implemented by a low temperature polycrystalline silicon (LTPS) thin film transistor. Therefore, when a voltage applied to the Q node Q is a low level which is a turn-on voltage, the 2-6-th transistor T2-6 applies the gate low voltage VGL to the output terminal Gout.

The 2-7-th transistor T2-7 is connected between a line which supplies a gate high voltage VGH and the output terminal Gout. For example, a source electrode of the 2-7-th transistor T2-7 is connected to the line which supplies the gate high voltage VGH and a drain electrode is connected to the output terminal Gout. Further, the gate electrode of the 2-7-th transistor T2-7 is connected to the QB node QB. The 2-7-th transistor T2-7 may be a p-type MOSFET (PMOS) and may be implemented by a low temperature polycrystalline silicon (LTPS) thin film transistor. Therefore, when a voltage applied to the QB node QB is a low level which is a turn-on voltage, the 2-7-th transistor T2-7 applies the gate high voltage VGH to the output terminal Gout.

The 2-1-th capacitor C_ON is connected between a line to which a clock signal CLK (n) of an n-th stage is applied and the QC node QC. The 2-1-th capacitor C_ON has a first electrode connected a line to which a clock signal CLK (n) of an n-th stage is applied and a second electrode connected to the QC node QC. Therefore, the 2-1-th capacitor C_ON may store a voltage applied to the QC node QC.

The 2-2-th capacitor CQ is connected between the Q node Q and the output terminal Gout. For example, a first electrode of the 2-2-th capacitor CQ is connected to the Q node Q and a second electrode is connected to the output terminal Gout. Therefore, the 2-2-th capacitor CQ may store a voltage applied to the Q node Q.

The 2-3-th capacitor CQB is connected between the QB node QB and a line which supplies a gate high voltage VGH. For example, the first electrode of the 2-3-th capacitor CQB is connected to the QB node QB and the second electrode is connected to the line which supplies the gate high voltage VGH. Therefore, the 2-3-th capacitor CQB may store a voltage applied to the QB node QB.

Hereinafter, the gate driver will be described in detail.

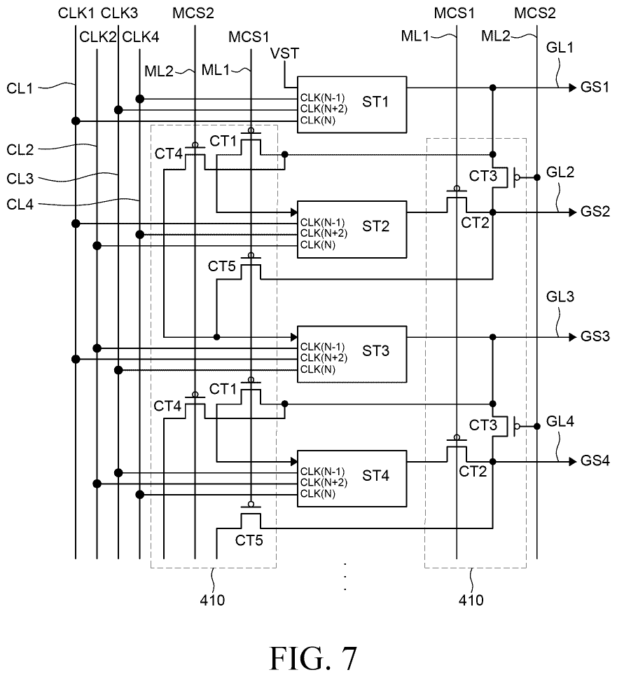

FIG. 7 is a schematic diagram of a gate driver to which a shift register circuit is applied, among gate drivers of a display device according to an example embodiment of the present disclosure. In FIG. 7, for the convenience of description, a first stage ST1 to a fourth stage ST4 which are some of the plurality of stages STn and a part of a mode controller 410 are illustrated.

Referring to FIG. 7, the gate drivers 401 and 402 include a plurality of stages STn and a mode controller 410.

The plurality of stages STn receives a start signal VST of the start signal line or an output of a previous stage STn-1 to output a gate signal GSn to a gate line GLn corresponding to each of the plurality of stages STn. The plurality of stages STn is supplied with at least three of clock signals CLK1 to CLK4 with different phases to output a gate signal. For example, the plurality of stages STn is supplied with a clock signal CLK (N) supplied to a N-th stage, a clock signal CLK (N-1) supplied to a N-1-th stage, and a clock signal CLK (N+2) supplied to a N+2-th stage.

Input terminals of the plurality of stages STn are connected to clock signal lines CL1 to CL4 and output terminals are connected to a plurality of gate lines GLn to output the gate signal through the plurality of gate lines GLn.

For example, an input terminal of the first stage ST1 is connected to a start signal line to which the start signal VST is supplied. Further, an input terminal of the first stage ST1 is connected to a first clock signal line CL1 to which a first clock signal CLK1 is supplied, a third clock signal line CL3 to which a third clock signal CLK3 is supplied, and a fourth clock signal line CL4 to which a fourth clock signal CLK4 is supplied. An output terminal of the first stage ST1 is connected to a first gate line GL1 disposed in the first pixel line PL1. Therefore, the first stage ST1 outputs the first gate signal GS1 through the first gate line GL1.

An input terminal of the second stage ST2 is connected to the output terminal of the previous stage ST1. Further, an input terminal of the second stage ST2 is connected to a first clock signal line CL1 to which a first clock signal CLK1 is supplied, a second clock signal line CL2 to which a second clock signal CLK2 is supplied, and a fourth clock signal line CL4 to which a fourth clock signal CLK4 is supplied. An output terminal of the second stage ST2 is connected to a second gate line GL2 disposed in the second pixel line PL2. Therefore, the second stage ST2 outputs the second gate signal GS2 through the second gate line GL2.

An input terminal of the third stage ST3 is connected to the output terminal of the previous stage ST2. Further, an input terminal of the third stage ST3 is connected to a first clock signal line CL1 to which a first clock signal CLK1 is supplied, a second clock signal line CL2 to which a second clock signal CLK2 is supplied, and a third clock signal line CL3 to which a third clock signal CLK3 is supplied. An output terminal of the third stage ST3 is connected to a third gate line GL3 disposed in the third pixel line PL3. Therefore, the third stage ST3 outputs the third gate signal GS3 through the third gate line GL3.

An input terminal of the fourth stage ST4 is connected to the output terminal of the previous stage ST3. Further, an input terminal of the fourth stage ST4 is connected to a second clock signal line CL2 to which a second clock signal CLK2 is supplied, a third clock signal line CL3 to which a third clock signal CLK3 is supplied, and a fourth clock signal line CL4 to which a fourth clock signal CLK4 is supplied. An output terminal of the fourth stage ST4 is connected to a fourth gate line GLA disposed in the fourth pixel line PL4. Therefore, the fourth stage ST4 outputs the fourth gate signal GS4 through the fourth gate line GL4.

The mode controller 410 is connected between the plurality of stages STn to control the operations of the gate drivers 401 and 402 according to a mode control signal.

The mode controller 410 includes a first control transistor CT1, a second control transistor CT2, a third control transistor CT3, a fourth control transistor CT4, and a fifth control transistor CT5.

The first control transistor CT1 is connected between an output terminal of a 2n-1-th stage and an input terminal of a 2n-th stage to be turned on according to the first mode control signal MCS1. For example, a source electrode of the first control transistor CT1 is connected between an output terminal of the first stage ST1 and a first gate line GL1 connected to an output terminal of the first stage ST1 and a drain electrode is connected to an input terminal of the second stage ST2. Further, a gate electrode of the first control transistor CT1 is connected to a first mode control signal line ML1 to which a first mode control signal MCS1 is applied. Further, the first control transistor CT1 may be a p-type MOSFET (PMOS) and may be implemented by a low temperature polycrystalline silicon (LTPS) thin film transistor. Therefore, when a voltage of the first mode control signal MCS1 is a low level which is a turn-on voltage, the first control transistor CT1 connects an output terminal of the first stage ST1 and an input terminal of the second stage ST2 to input a gate signal output from the first stage ST1 to the input terminal of the second stage ST2.

The second control transistor CT2 is connected between an output terminal of a 2n-th stage and a second gate line GL2 connected to an output terminal of a 2n-th stage to be turned on according to the first mode control signal MCS1. For example, a source electrode of the second control transistor CT2 is connected to an output terminal of the second stage ST2 and a drain electrode is connected to the second gate line GL2. Further, a gate electrode of the second control transistor CT2 is connected to a first mode control signal line ML1 to which a first mode control signal MCS1 is applied. Further, the second control transistor CT2 may be a p-type MOSFET (PMOS) and may be implemented by a low temperature polycrystalline silicon (LTPS) thin film transistor. Therefore, when a voltage of the first mode control signal MCS1 is a low level which is a turn-on voltage, the second control transistor CT2 connects the output terminal of the second stage ST2 and the second gate line GL2 to supply a gate signal output from the second stage ST2 through the second gate line GL2.

The third control transistor CT3 is connected between an output terminal of the 2n-1-th stage and an output terminal of the 2n-th stage to be turned on according to the second mode control signal MCS2. For example, a source electrode of the third control transistor CT3 is connected to the first gate line GL1 connected to the output terminal of the first stage ST1 and a drain electrode is connected to the second gate line GL2 connected to the output terminal of the second stage ST2. Further, a gate electrode of the third control transistor CT3 is connected to a second mode control signal line ML2 to which a second mode control signal MCS2 is applied.

Further, the third control transistor CT3 may be a p-type MOSFET (PMOS) and may be implemented by a low temperature polycrystalline silicon (LTPS) thin film transistor. Therefore, when a voltage of the second mode control signal MCS2 is a low level which is a turn-on voltage, the third control signal CT3 connects the first gate line GL1 and the second gate line GL2 to supply a gate signal output from the first stage ST1 through the first gate line GL1 and the second gate line GL2.

The fourth control transistor CT4 is connected between an output terminal of a 2n-1-th stage and an input terminal of a 2n+1-th stage to be turned on according to the second mode control signal MCS2. For example, a source electrode of the fourth control transistor CT4 is connected to an output terminal of the first stage ST1 and a drain electrode is connected to an input terminal of the third stage ST3. Further, a gate electrode of the fourth control transistor CT4 is connected to a second mode control signal line ML2 to which the second mode control signal MCS2 is applied. Further, the fourth control transistor CT4 may be a p-type MOSFET (PMOS) and may be implemented by a low temperature polycrystalline silicon (LTPS) thin film transistor. Therefore, when a voltage of the second mode control signal MCS2 is a low level which is a turn-on voltage, the fourth control transistor CT4 connects an output terminal of the first stage ST1 and an input terminal of the third stage ST3 to input a gate signal output from the first stage ST1 to the input terminal of the third stage ST3.

The fifth control transistor CT5 is connected between an output terminal of a 2n-th stage and an input terminal of a 2n+1-th stage to be turned on according to the first mode control signal MCS1. For example, a source electrode of the fifth control transistor CT5 is connected to an output terminal of the second stage ST2 and a drain electrode is connected to an input terminal of the third stage ST3. Further, a gate electrode of the fifth control transistor CT5 is connected to the first mode control signal line ML1 to which the first mode control signal MCS1 is applied. Further, the fifth control transistor CT5 may be a p-type MOSFET (PMOS) and may be implemented by a low temperature polycrystalline silicon (LTPS) thin film transistor. Therefore, when a voltage of the first mode control signal MCS1 is a low level which is a turn-on voltage, the fifth control transistor CT5 connects an output terminal of the second stage ST2 and an input terminal of the third stage ST3 to input a gate signal output from the second stage ST2 to the input terminal of the third stage ST3.

Hereinafter, an operation of the gate driver in a first mode and a second mode will be described in detail.

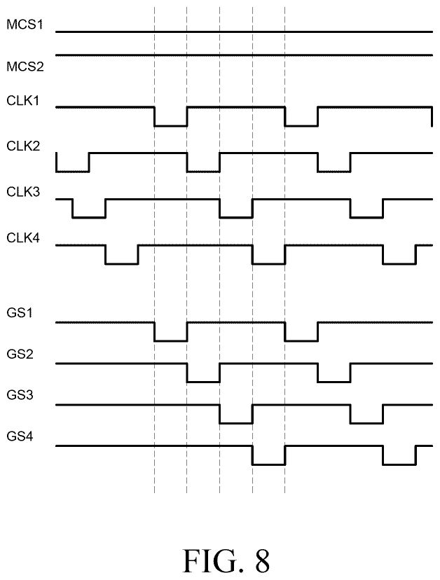

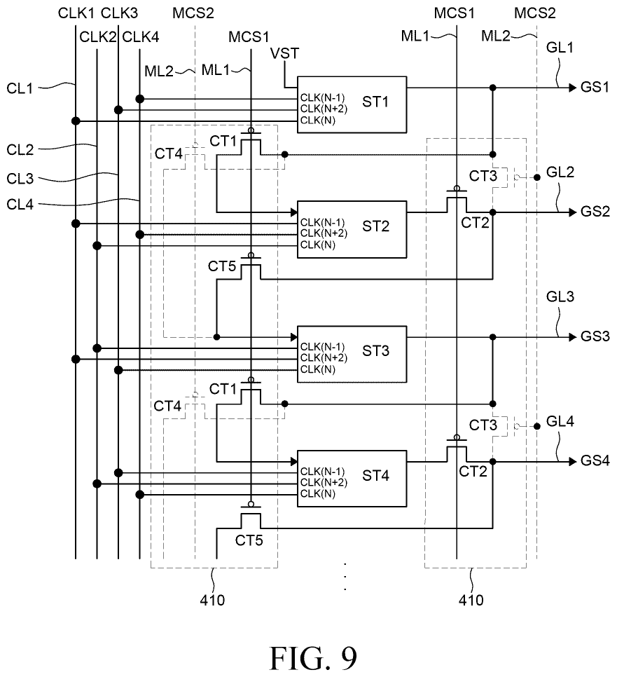

FIG. 8 is a waveform diagram illustrating various signals in a first mode operation of a gate driver of FIG. 7. FIG. 9 is a schematic diagram for explaining a first mode operation of a gate driver of FIG. 7. In FIGS. 8 and 9, an example that the plurality of stages STn is configured by a shift register circuit will be described. In FIGS. 8 and 9, an example that the gate driver operates in a first mode will be described.

Referring to FIGS. 8 and 9, a low level of first mode control signal MCS1 which is a turn-on voltage is applied to the first mode control signal line ML1 and a high level of second mode control signal MCS2 which is a turn-off voltage is applied to the second mode control signal line ML2.

In this case, the first control transistor CT1, the second control transistor CT2, and the fifth control transistor CT5 are turned on and the third control transistor CT3 and the fourth control transistor CT4 are turned off.

Therefore, all the plurality of stages ST1 to ST4 is dependently connected so that a gate signal output from a previous stage is input to an input terminal of a next stage. Further, the plurality of stages ST1 to ST4 sequentially outputs gate signals GS1 to GS4 through connected gate lines GL1 to GL4 according to timings of clock signals CLK1 to CLK4 input to each stage ST1 to ST4.

For example, the first gate signal GS1 output from the first stage ST1 is supplied to the first gate line GL1 and is input to an input terminal of the second stage ST2. The second gate signal GS2 output from the second stage ST2 is supplied to the second gate line GL2 and is input to an input terminal of the third stage ST3. The third gate signal GS3 output from the third stage ST3 is supplied to the third gate line GL3 and is input to an input terminal of the fourth stage ST4. The fourth gate signal GS4 output from the fourth stage ST4 is supplied to the fourth gate line GL4 and is input to an input terminal of a next stage.

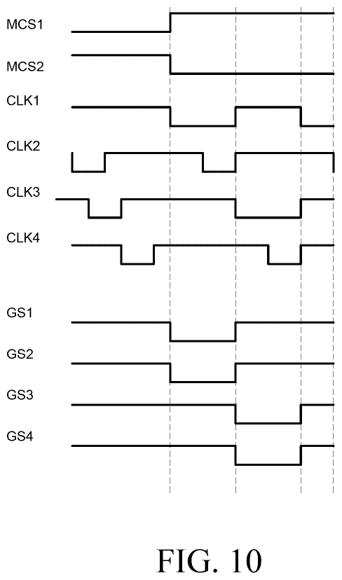

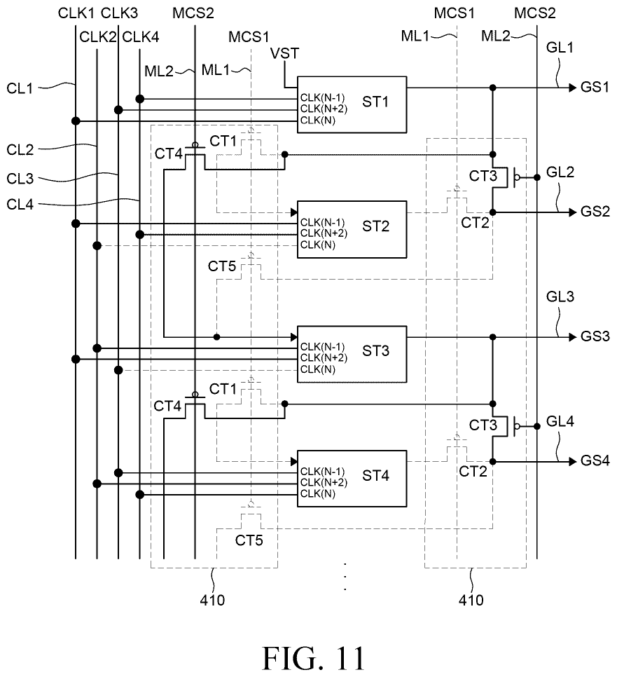

FIG. 10 is a waveform diagram illustrating various signals in a second mode operation of a gate driver of FIG. 7. FIG. 11 is a schematic diagram for explaining a second mode operation of a gate driver of FIG. 7. In FIGS. 10 and 11, an example that the plurality of stages STn is configured by a shift register circuit will be described. In FIGS. 10 and 11, an example that the gate driver operates in a second mode will be described.

Referring to FIGS. 10 and 11, a low level of second mode control signal MCS2 which is a turn-on voltage is applied to the second mode control signal line ML2 and a high level of first mode control signal MCS1 which is a turn-off voltage is applied to the first mode control signal line ML1.

In this case, the third control transistor CT3 and the fourth control transistor CT4 are turned on and the first control transistor CT1, the second control transistor CT2, and the fifth control transistor CT5 are turned off.

Therefore, only odd-numbered stages ST1 and ST3 among the plurality of stages ST1 to ST4 are dependently connected so that a gate signal output from a previous stage is input to an input terminal of a next stage. Further, clock signals CLK1 and CLK3 are input to only the odd-numbered stages ST1 and ST3. The odd-numbered stages ST1 and ST3 sequentially output the gate signals GS1 and GS3 through odd-numbered gate lines GL1 and GL3 and even-numbered gate lines GL2 and GL4 adjacent to the odd-numbered gate lines GL1 and GL3 according to falling edge timings of the clock signal CLK1 and CLK3.

For example, the first gate signal GS1 output from the first stage ST1 is supplied to the first gate line GL1 and the second gate line GL2 and is input to an input terminal of the third stage ST3. The third gate signal GS3 output from the third stage ST3 is supplied to the third gate line GL3 and the fourth gate line GLA and then is input to an input terminal of an odd-numbered stage.

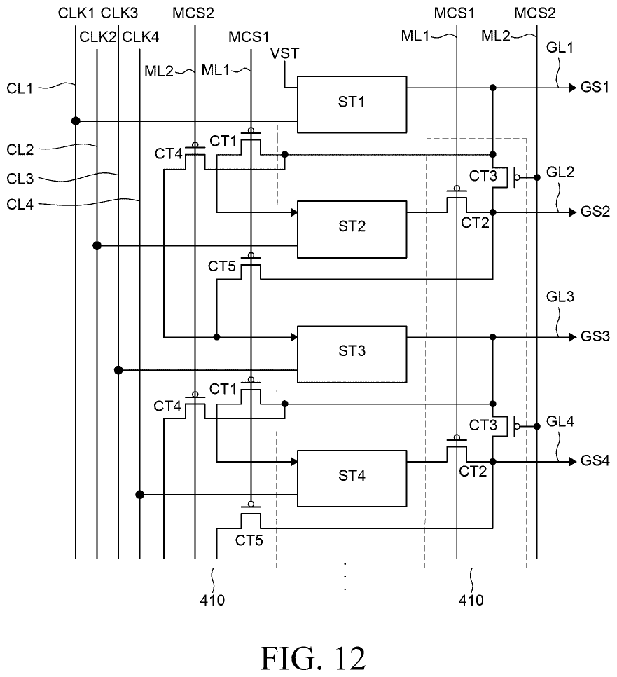

FIG. 12 is a schematic diagram of a gate driver to which an edge trigger circuit is applied, among gate drivers of a display device according to an example embodiment of the present disclosure. In FIG. 12, the remaining configuration except a connection relationship of a plurality of stages STn and clock signal lines CL1 to CL4 is the same as that in FIG. 7 so that a detailed description will be omitted. In FIG. 12, for the convenience of description, only a first stage ST1 to a fourth stage ST4 which are some of the plurality of stages STn and a part of a mode controller 410 are illustrated.

Referring to FIG. 12, the gate drivers 401 and 402 include a plurality of stages STn and a mode controller 410.

The plurality of stages STn receives a start signal VST of the start signal line or an output of a previous stage STn-1 to output a gate signal GSn to a gate line GLn corresponding to each of the plurality of stages STn. The plurality of stages STn is supplied with at least one of clock signals CLK1 to CLK4 with different phases to output a gate signal. For example, the plurality of stages STn is supplied with a clock signal CLK (N) supplied to an N-th stage.

Input terminals of the plurality of stages STn are connected to clock signal lines CL1 to CL4 and output terminals are connected to a plurality of gate lines GLn to output the gate signal through the plurality of gate lines GLn.

For example, an input terminal of the first stage ST1 is connected to a start signal line to which the start signal VST is supplied. Further, the input terminal of the first stage ST1 is connected to the first clock signal line CL1 to which the first clock signal CLK1 is supplied. An output terminal of the first stage ST1 is connected to a first gate line GL1 disposed in the first pixel line PL1. Therefore, the first stage ST1 outputs the first gate signal GS1 through the first gate line GL1.

An input terminal of the second stage ST2 is connected to the output terminal of the previous stage ST1. Further, the input terminal of the second stage ST2 is connected to the second clock signal line CL2 to which the second clock signal CLK2 is supplied. An output terminal of the second stage ST2 is connected to a second gate line GL2 disposed in the second pixel line PL2. Therefore, the second stage ST2 outputs the second gate signal GS2 through the second gate line GL2.

An input terminal of the third stage ST3 is connected to the output terminal of the previous stage ST2. Further, the input terminal of the third stage ST3 is connected to the third clock signal line CL3 to which the third clock signal CLK3 is supplied. An output terminal of the third stage ST3 is connected to a third gate line GL3 disposed in the third pixel line PL3. Therefore, the third stage ST3 outputs the third gate signal GS3 through the third gate line GL3.

An input terminal of the fourth stage ST4 is connected to the output terminal of the previous stage ST3. Further, the input terminal of the fourth stage ST4 is connected to the fourth clock signal line CL4 to which the fourth clock signal CLK4 is supplied. An output terminal of the fourth stage ST4 is connected to a fourth gate line GL4 disposed in the fourth pixel line PL4. Therefore, the fourth stage ST4 outputs the fourth gate signal GS4 through the fourth gate line GL4.

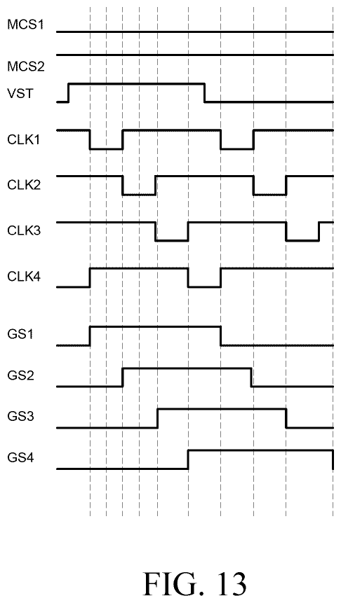

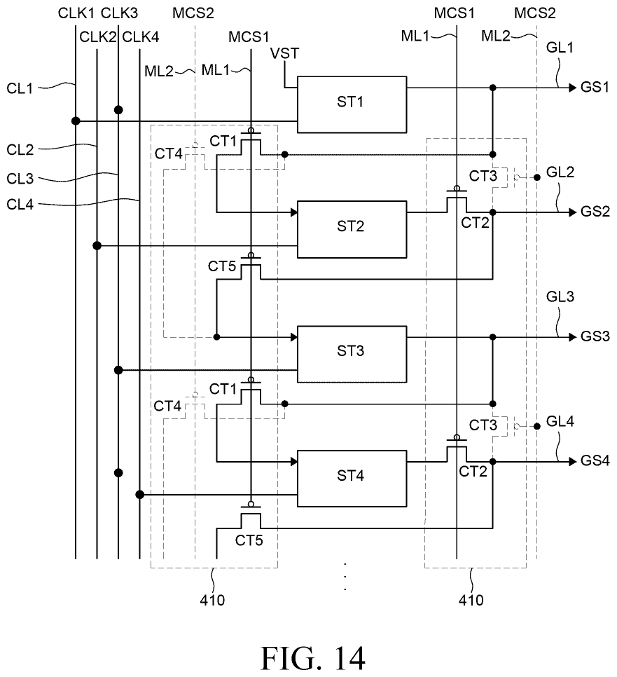

FIG. 13 is a waveform diagram illustrating various signals in a first mode operation of a gate driver of FIG. 12. FIG. 14 is a schematic diagram for explaining a second mode operation of a gate driver of FIG. 12. In FIGS. 13 and 14, an example that the plurality of stages STn is configured by an edge trigger circuit will be described. In FIGS. 13 and 14, an example that the gate driver operates in a first mode will be described.

Referring to FIGS. 13 and 14, a low level of first mode control signal MCS1 which is a turn-on voltage is applied to the first mode control signal line ML1 and a high level of second mode control signal MCS2 which is a turn-off voltage is applied to the second mode control signal line ML2.

In this case, the first control transistor CT1, the second control transistor CT2, and the fifth control transistor CT5 are turned on and the third control transistor CT3 and the fourth control transistor CT4 are turned off.

Therefore, all the plurality of stages ST1 to ST4 is dependently connected so that a gate signal output from a previous stage is input to an input terminal of a next stage. Further, the plurality of stages ST1 to ST4 sequentially outputs gate signals GS1 to GS4 through connected gate lines GL1 to GL4 according to fall edges of clock signals CLK1 to CLK4 input to each stage ST1 to ST4.

For example, the first gate signal GS1 output from the first stage ST1 is supplied to the first gate line GL1 and is input to an input terminal of the second stage ST2. The second gate signal GS2 output from the second stage ST2 is supplied to the second gate line GL2 and is input to an input terminal of the third stage ST3. The third gate signal GS3 output from the third stage ST3 is supplied to the third gate line GL3 and is input to an input terminal of the fourth stage ST4. The fourth gate signal GS4 output from the fourth stage ST4 is supplied to the fourth gate line GL4 and is input to an input terminal of a next stage.

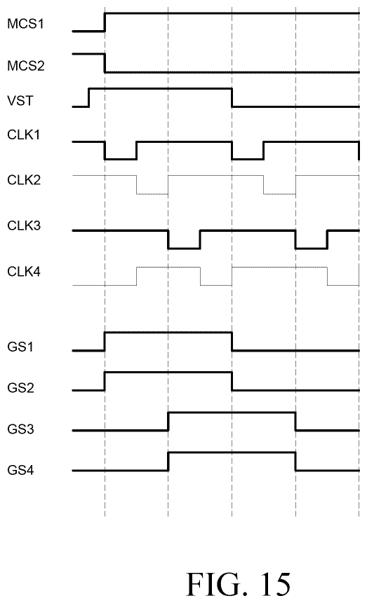

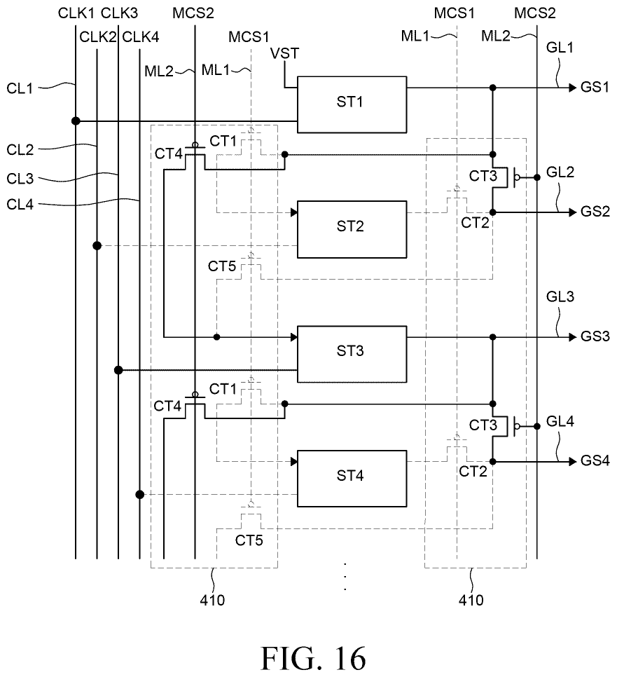

FIG. 15 is a waveform diagram illustrating various signals in a second mode operation of a gate driver of FIG. 12. FIG. 16 is a schematic view for explaining a second mode operation of a gate driver of a display device according to an example embodiment of the present disclosure. In FIGS. 15 and 16, an example that the plurality of stages STn is configured by an edge trigger circuit will be described. In FIGS. 15 and 16, an example that the gate driver operates in a second mode will be described.

Referring to FIGS. 15 and 16, a low level of second mode control signal MCS2 which is a turn-on voltage is applied to the second mode control signal line ML2 and a high level of first mode control signal MCS1 which is a turn-off voltage is applied to the first mode control signal line ML1.

In this case, the third control transistor CT3 and the fourth control transistor CT4 are turned on and the first control transistor CT1, the second control transistor CT2, and the fifth control transistor CT5 are turned off.

Therefore, only odd-numbered stages ST1 and ST3 among the plurality of stages ST1 to ST4 are dependently connected so that a gate signal output from a previous stage is input to an input terminal of a next stage. Further, clock signals CLK1 and CLK3 are input to only the odd-numbered stages ST1 and ST3. The odd-numbered stages ST1 and ST3 sequentially output the gate signals GS1 and GS3 through odd-numbered gate lines GL1 and GL3 and even-numbered gate lines GL2 and GL4 adjacent to the odd-numbered gate lines GL1 and GL3 according to falling edge timings of the clock signal CLK1 and CLK3.

For example, the first gate signal GS1 output from the first stage ST1 is supplied to the first gate line GL1 and the second gate line GL2 and is input to an input terminal of the third stage ST3. The third gate signal GS3 output from the third stage ST3 is supplied to the third gate line GL3 and the fourth gate line GLA and then is input to an input terminal of an odd-numbered stage.

Accordingly, in the display device 1000 according to the example embodiment of the present disclosure, when the gate drivers 401 and 402 operate in the first mode, gate signals GS1 to GS4 output from the plurality of stages ST1 to ST4 are output to the gate lines GL1 to GL4 connected to the plurality of stages. Further, when the gate drivers 401 and 402 operate in a second mode, gate signals GS1 and GS3 output from the odd-numbered stages ST1 and ST3, among the plurality of stages ST1 to ST4 are output to the gate lines GL1 and GL3 connected to the odd-numbered stages ST1 and ST3 and the gate line GL2 and GLA connected to the even-numbered stages ST2 and ST4.

For example, when the gate drivers 401 and 402 operate in a high resolution mode, the first gate signal GS1 output from the first stage ST1 is supplied to the first gate line GL1 and the second gate signal GS2 output from the second stage ST2 is supplied to the second gate line GL2. The third gate signal GS3 output from the third stage ST3 is supplied to the third gate line GL3 and the fourth gate signal GS4 output from the fourth stage ST4 is supplied to the fourth gate line GL4.

For example, when the gate drivers 401 and 402 operate in a low resolution mode, the first gate signal GS1 output from the first stage ST1 is supplied to the first gate line GL1 and the second gate line GL2 and the third gate signal GS3 output from the third stage ST3 is supplied to the third gate line GL3 and the fourth gate line GL4.

When the display device 1000 according to the example embodiment of the present disclosure is driven to be divided into the first active area AA1 and the second active area AA2, an image displayed in the first active area AA1 needs to be driven at a high resolution, like a moving image, and an image displayed in the second active area AA2 needs to be driven at a low resolution, like a still image. At this time, the mode controller 410 controls the gate drivers 401 and 402 to operate in a high resolution mode or a low resolution mode. Therefore, when the gate drivers 401 and 402 operate in a high resolution mode, all the plurality of stages ST1 to ST4 operate to supply the gate signals GS1 to GS4 to the gate lines GL1 to GL4 connected to the plurality of stages. When the gate drivers 401 and 402 operate in a low resolution mode, only some stages ST1 and ST3, among the plurality of stages ST1 to ST4, operate to supply the same gate signals GS1 and GS3 to the odd-numbered gate lines GL1 and GL3 and even-numbered gate lines GL2 and GL4 adjacent to the odd-numbered gate lines GL1 and GL3. Accordingly, when a partial area of the active area operates at a low resolution, some stages of the gate driver may not operate. Further, when the stage is an edge trigger circuit, a configuration which outputs some clock signal is turned off so as not to supply a clock signal to a stage which does not operate so that the driving IC is driven with a low power to reduce the power consumption.

Therefore, in the display device 1000 according to the example embodiment of the present disclosure, when the gate drivers 401 and 402 operate in a high resolution mode, all the plurality of stages ST1 to ST4 operate to supply the gate signals GS1 to GS4 to the gate lines GL1 to GLA connected to the plurality of stages. When the gate drivers 401 and 402 operate in a low resolution mode, only some stages ST1 and ST3, among the plurality of stages ST1 to ST4, operate to supply the same gate signals GS1 and GS3 to the odd-numbered gate lines GL1 and GL3 and even-numbered gate lines GL2 and GL4 adjacent to the odd-numbered gate lines GL1 and GL3. Accordingly, even though the active area is divided to be driven at different resolutions, a driving frequency of the overall active area is not lowered so that only a partial area of the divided active area is changed to a low resolution while operating at a high speed. Further, a high resolution area and a low resolution area can be changed so as to respond to various contents.

Hereinafter, another example embodiment of the present disclosure will be described with reference to the drawings.

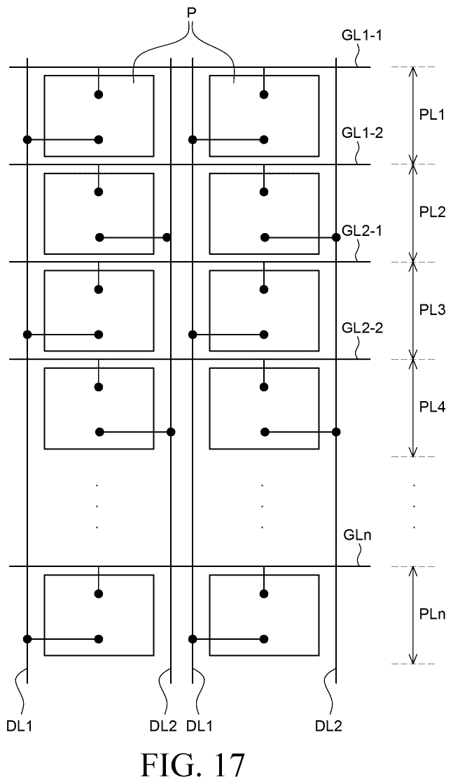

FIG. 17 is a schematic view for explaining an active area of a display device according to another example embodiment of the present disclosure. In FIG. 17, the remaining configuration excluding data lines DL1 and DL2 is the same as that in FIG. 2 so that a redundant description will be omitted.

Referring to FIG. 17, in the active area AA, a plurality of gate lines GLn-1 and GLn-2 disposed in a first direction and a plurality of data lines DL1 and DL2 disposed in a second direction which is different from the first direction are disposed. The plurality of gate lines GLn-1 and GLn-2 and the plurality of data lines DL1 and DL2 may intersect and the plurality of pixels P may be disposed in a matrix.

The plurality of data lines DL1 and DL2 includes a first data line DL1 and a second data line DL2.

The first data line DL1 is connected to the pixel P disposed in the odd-numbered pixel lines PL1 and PL3. For example, the first data line DL1 is disposed at a left side of the pixel P and is electrically connected to a first pixel line PL1 and a third pixel line PL3. Therefore, the first data line DL1 supplies a data voltage to the pixels P disposed in odd-numbered pixel lines PL1 and PL3.

The second data line DL2 is connected to the pixel P disposed in the even-numbered pixel lines PL2 and PL4. For example, the second data line DL2 is disposed at a right side of the pixel P and is electrically connected to a second pixel line PL2 and a fourth pixel line PL4. Therefore, the second data line DL2 supplies a data voltage to the pixels P disposed in even-numbered pixel lines PL2 and PL4.

Hereinafter, a gate driver according to another example embodiment of the present disclosure will be described in detail.

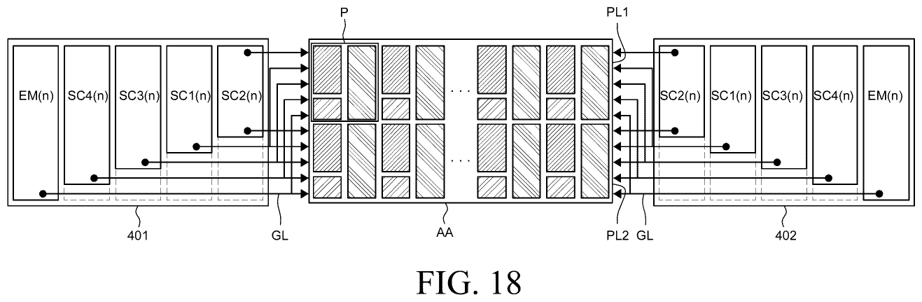

FIG. 18 is a functional block diagram of a gate driver of a display device according to another example embodiment of the present disclosure. In FIG. 18, for the convenience of description, only gate drivers 401 and 402 for two pixel lines PL1 and PL2 are illustrated. In FIG. 18, the remaining configuration except gate lines connected to pixel lines PL1 and PL2 is the same as that in FIG. 4 so that a detailed description will be omitted.

Referring to FIG. 18, the gate drivers 401 and 402 are disposed symmetrically in the non-active areas NA on both sides of the active area AA to supply scan signals Scan1 to Scan4 to the plurality of pixels P and supply an emission signal EM(n) to the plurality of pixels P.

Each of the gate drivers 401 and 402 includes a first scan driver SC1(n), a second scan driver SC2(n), a third scan driver SC3(n), a fourth scan driver SC4(n), and an emission driver EM(n).

Each of the first scan driver SC1(n), the second scan driver SC2(n), the third scan driver SC3(n), the fourth scan driver SC4(n), and the emission driver EM(n) is connected to the gate line to supply scan signals Scan1 to Scan4 to the plurality of pixels P and an emission signal EM(n) to the plurality of pixels P.

Each of the first scan driver SC1(n), the second scan driver SC2(n), the third scan driver SC3(n), the fourth scan driver SC4(n), and the emission driver EM(n) supplies the scan signals Scan1 to Scan4 and the emission signal EM(n) to the pixels P disposed in two pixel lines PL1 and PL2.

Hereinafter, a gate driver according to another example embodiment of the present disclosure will be described in detail.

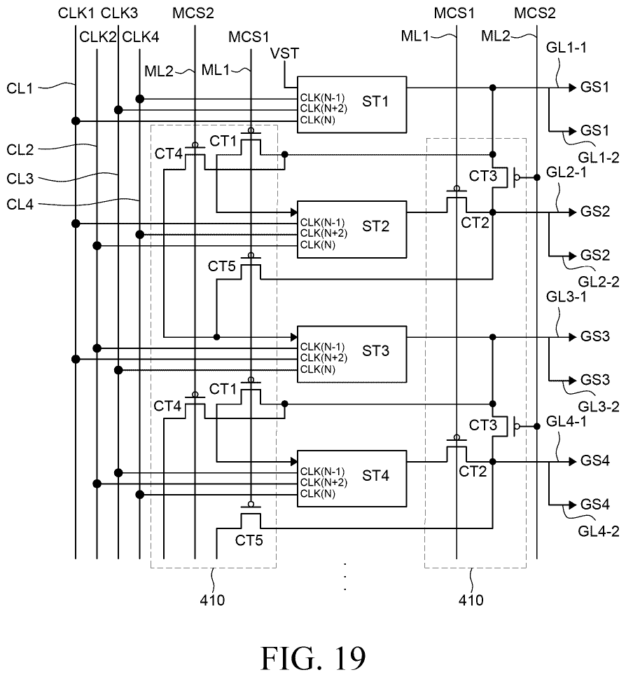

FIG. 19 is a schematic diagram of a gate driver to which a shift register circuit is applied, among gate drivers of a display device according to another example embodiment of the present disclosure. In FIG. 19, for the convenience of description, only a first stage ST1 to a fourth stage ST4 which are some of the plurality of stages STn and a part of a mode controller 410 are illustrated. In FIG. 19, the remaining configuration except gate lines connected to a plurality of stages STn is the same as that in FIG. 7 so that a detailed description will be omitted.

Referring to FIG. 19, the gate drivers 401 and 402 include a plurality of stages STn and a mode controller 410.

The plurality of stages STn receives a start signal VST of the start signal line or an output of a previous stage STn-1 to output a gate signal GSn to a gate line GLn corresponding to each of the plurality of stages STn. The plurality of stages STn is supplied with at least three of clock signals CLK1 to CLK4 with different phases to output a gate signal. For example, the plurality of stages STn is supplied with a clock signal CLK (N) supplied to a N-th stage, a clock signal CLK (N-1) supplied to a N-1-th stage, and a clock signal CLK (N+2) supplied to a N+2-th stage.

Input terminals of the plurality of stages STn are connected to clock signal lines CL1 to CL4 and output terminals are connected to a plurality of gate lines GLn to output the gate signal through the plurality of gate lines GLn.

The plurality of gate lines GLn includes a first gate line GLn-1 and a second gate line GLn-2 which are connected to the plurality of stages STn and supply the same gate signal to pixels P disposed in two adjacent pixel lines.

For example, an input terminal of the first stage ST1 is connected to a start signal line to which the start signal VST is supplied. Further, an input terminal of the first stage ST1 is connected to a first clock signal line CL1 to which a first clock signal CLK1 is supplied, a third clock signal line CL3 to which a third clock signal CLK3 is supplied, and a fourth clock signal line CL4 to which a fourth clock signal CLK4 is supplied. An output terminal of the first stage ST1 is connected to a 1-1-th gate line GL1-1 disposed in the first pixel line PL1 and a 1-2-th gate line GL1-2 disposed in the second pixel line PL2. Therefore, the first stage ST1 outputs the same first gate signal GS1 to pixels P disposed in two adjacent pixel lines PL1 and PL2 through the 1-1-th gate line GL1-1 and the 1-2-th gate line GL1-2.

An input terminal of the second stage ST2 is connected to the output terminal of the previous stage ST1. Further, an input terminal of the second stage ST2 is connected to a first clock signal line CL1 to which a first clock signal CLK1 is supplied, a second clock signal line CL2 to which a second clock signal CLK2 is supplied, and a fourth clock signal line CL4 to which a fourth clock signal CLK4 is supplied. An output terminal of the second stage ST2 is connected to a 2-1-th gate line GL2-1 disposed in the third pixel line PL3 and a 2-2-th gate line GL2-2 disposed in the fourth pixel line PLA. Therefore, the second stage ST2 outputs the same second gate signal GS2 to pixels P disposed in two adjacent pixel lines PL3 and PL4 through the 2-1-th gate line GL2-1 and the 2-2-th gate line GL2-2.

An input terminal of the third stage ST3 is connected to the output terminal of the previous stage ST2. Further, an input terminal of the third stage ST3 is connected to a first clock signal line CL1 to which a first clock signal CLK1 is supplied, a second clock signal line CL2 to which a second clock signal CLK2 is supplied, and a third clock signal line CL3 to which a third clock signal CLK3 is supplied. An output terminal of the third stage ST3 is connected to a 3-1-th gate line GL3-1 disposed in the fifth pixel line PL5 and a 3-2-th gate line GL3-2 disposed in the sixth pixel line PL6. Therefore, the third stage ST3 outputs the same third gate signal GS3 to pixels P disposed in two adjacent pixel lines PL5 and PL6 through the 3-1-th gate line GL3-1 and the 3-2-th gate line GL3-2.

An input terminal of the fourth stage ST4 is connected to the output terminal of the previous stage ST3. Further, an input terminal of the fourth stage ST4 is connected to a second clock signal line CL2 to which a second clock signal CLK2 is supplied, a third clock signal line CL3 to which a third clock signal CLK3 is supplied, and a fourth clock signal line CL4 to which a fourth clock signal CLK4 is supplied. An output terminal of the fourth stage ST4 is connected to a 4-1-th gate line GL4-1 disposed in the seventh pixel line PL7 and a 4-2-th gate line GL4-2 disposed in the eighth pixel line PL8. Therefore, the fourth stage ST4 outputs the same fourth gate signal GS4 to pixels P disposed in two adjacent pixel lines PL7 and PL8 through the 4-1-th gate line GL4-1 and the 4-2-th gate line GL4-2.

Hereinafter, an operation of the gate driver in a first mode and a second mode will be described in detail.

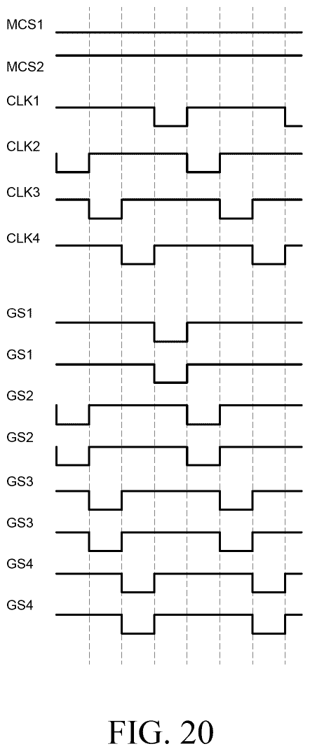

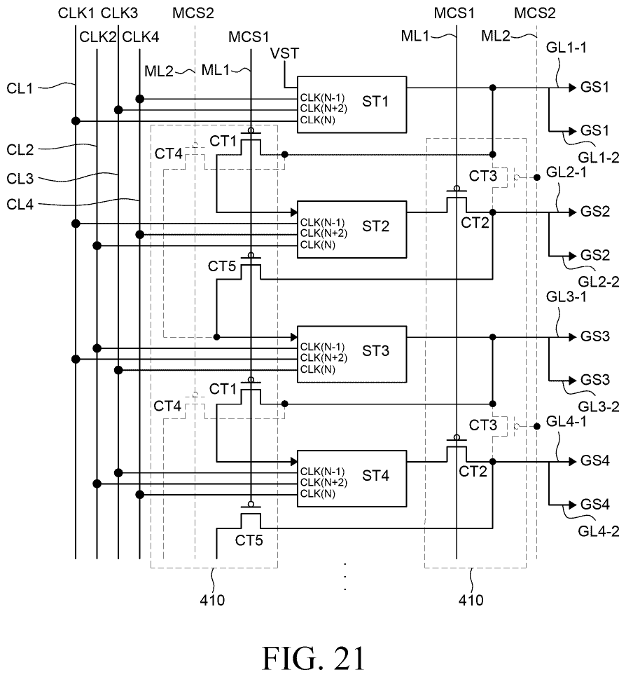

FIG. 20 is a waveform diagram illustrating various signals in a first mode operation of a gate driver of FIG. 19. FIG. 21 is a schematic diagram for explaining a first mode operation of a gate driver of FIG. 19. In FIGS. 20 and 21, an example that the plurality of stages STn is configured by a shift register circuit will be described. In FIGS. 20 and 21, an example that the gate driver operates in a first mode will be described.

Referring to FIGS. 20 and 21, a low level of first mode control signal MCS1 which is a turn-on voltage is applied to the first mode control signal line ML1 and a high level of second mode control signal MCS2 which is a turn-off voltage is applied to the second mode control signal line ML2.

In this case, the first control transistor CT1, the second control transistor CT2, and the fifth control transistor CT5 are turned on and the third control transistor CT3 and the fourth control transistor CT4 are turned off.

Therefore, all the plurality of stages ST1 to ST4 is dependently connected so that a gate signal output from a previous stage is input to an input terminal of a next stage. Further, the plurality of stages ST1 to ST4 sequentially outputs gate signals GS1 to GS4 through connected gate lines GL1-1 to GL4-2 according to timings of clock signals CLK1 to CLK4 input to each stage ST1 to ST4.

For example, the first gate signal GS1 output from the first stage ST1 is supplied to the 1-1-th gate line GL1-1 and the 1-2-th gate line GL1-2 and is input to an input terminal of the second stage ST2. The second gate signal GS2 output from the second stage ST2 is supplied to a 2-1-th gate line GL2-1 and a 2-2-th gate line GL2-2 and is input to an input terminal of the third stage ST3. The third gate signal GS3 output from the third stage ST3 is supplied to a 3-1-th gate line GL3-1 and a 3-2-th gate line GL3-2 and is input to an input terminal of the fourth stage ST4. The fourth gate signal GS4 output from the fourth stage ST4 is supplied to a 4-1-th gate line GL4-1 and a 4-2-th gate line GL4-2 and is input to an input terminal of the next stage.

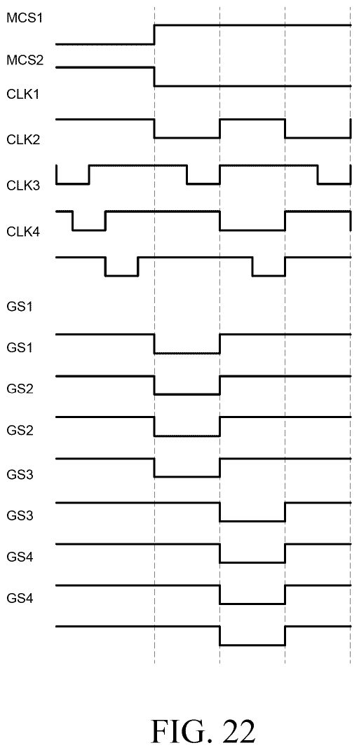

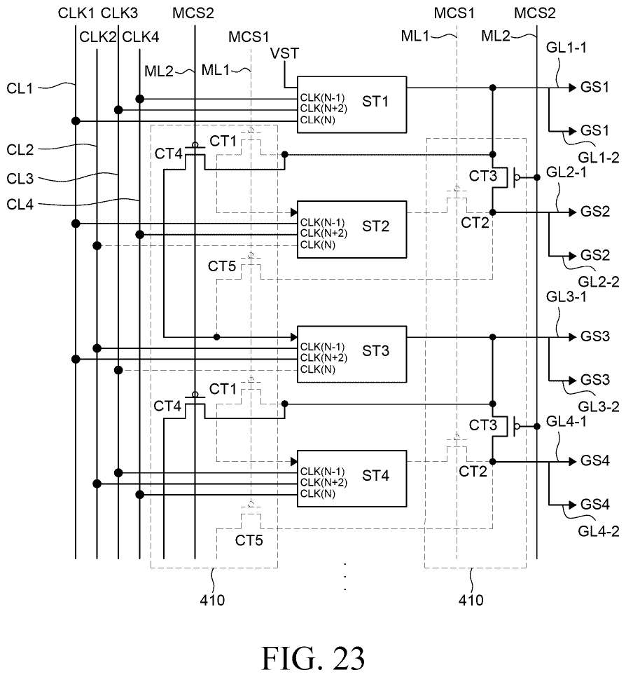

FIG. 22 is a waveform diagram illustrating various signals in a second mode operation of a gate driver of FIG. 19. FIG. 23 is a schematic diagram for explaining a second mode operation of a gate driver of FIG. 19. In FIGS. 22 and 23, an example that the plurality of stages STn is configured by a shift register circuit will be described. In FIGS. 22 and 23, an example that the gate driver operates in a second mode will be described.

Referring to FIGS. 22 and 23, a low level of second mode control signal MCS2 which is a turn-on voltage is applied to the second mode control signal line ML2 and a high level of first mode control signal MCS1 which is a turn-off voltage is applied to the first mode control signal line ML1.

In this case, the third control transistor CT3 and the fourth control transistor CT4 are turned on and the first control transistor CT1, the second control transistor CT2, and the fifth control transistor CT5 are turned off.

Therefore, only odd-numbered stages ST1 and ST3 among the plurality of stages ST1 to ST4 are dependently connected so that a gate signal output from a previous stage is input to an input terminal of a next stage. Further, clock signals CLK1 and CLK3 are input to only the odd-numbered stages ST1 and ST3. The odd-numbered stages ST1 and ST3 sequentially output the gate signals GS1 and GS3 through odd-numbered gate lines GL1-1, GL1-2, GL3-1, and GL3-2 and even-numbered gate lines GL2-1, GL2-2, GL4-1, and GL4-2 adjacent to the odd-numbered gate lines GL1-1, GL1-2, GL3-1, and GL3-2 according to falling edge timings of the clock signal CLK1 and CLK3.

For example, the first gate signal GS1 output from the first stage ST1 is supplied to the 1-1-th gate line GL1-1, the 1-2-th gate line GL1-2, the 2-1-th gate line GL2-1, and the 2-2-th gate line GL2-2 and is input to an input terminal of the third stage ST3. The third gate signal GS3 output from the third stage ST3 is supplied to a 3-1-th gate line GL3-1, a 3-2-th gate line GL3-2, a 4-1-th gate line GL4-1, and a 4-2-th gate line GL4-2 and is then input to an input terminal of an odd-numbered stage.

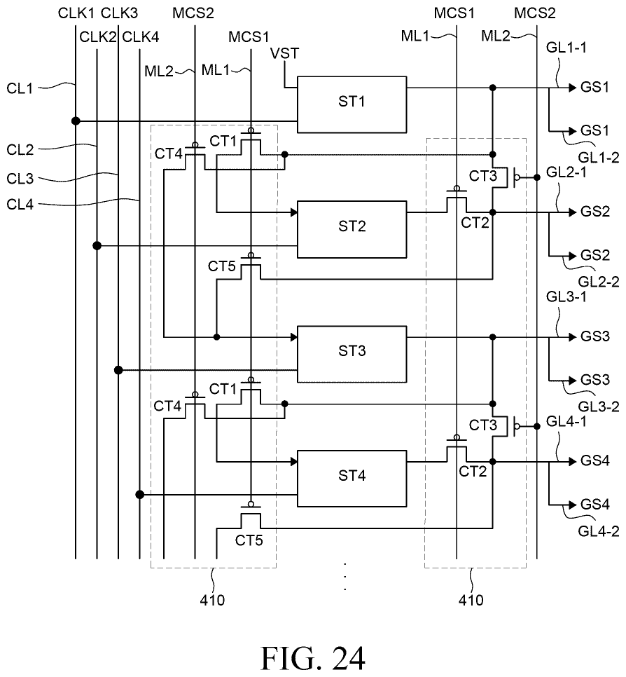

FIG. 24 is a schematic diagram of a gate driver to which an edge trigger circuit is applied, among gate drivers of a display device according to another example embodiment of the present disclosure. In FIG. 24, the remaining configuration except a connection relationship of a plurality of stages STn and clock signal lines CL1 to CL4 is the same as that in FIG. 19 so that a detailed description will be omitted. In FIG. 24, for the convenience of description, a first stage ST1 to a fourth stage ST4 which are some of the plurality of stages STn and a part of a mode controller 410 are illustrated.

The plurality of stages STn receives a start signal VST of the start signal line or an output of a previous stage STn-1 to output a gate signal GSn to a gate line GLn corresponding to each of the plurality of stages STn. The plurality of stages STn is supplied with at least one of clock signals CLK1 to CLK4 with different phases to output a gate signal. For example, the plurality of stages STn is supplied with a clock signal CLK (N) supplied to an N-th stage.

Input terminals of the plurality of stages STn are connected to clock signal lines CL1 to CL4 and output terminals are connected to a plurality of gate lines GLn to output the gate signal through the plurality of gate lines GLn.

The plurality of gate lines GLn includes a first gate line GLn-1 and a second gate line GLn-2 which are connected to the plurality of stages STn and supply the same gate signal to pixels P disposed in two adjacent pixel lines.

For example, an input terminal of the first stage ST1 is connected to a start signal line to which the start signal VST is supplied. Further, the input terminal of the first stage is connected to the first clock signal line CL1 to which the first clock signal CLK1 is supplied. An output terminal of the first stage ST1 is connected to a 1-1-th gate line GL1-1 disposed in the first pixel line PL1 and a 1-2-th gate line GL1-2 disposed in the second pixel line PL2. Therefore, the first stage ST1 outputs the same first gate signal GS1 to pixels P disposed in two adjacent pixel lines PL1 and PL2 through the 1-1-th gate line GL1-1 and the 1-2-th gate line GL1-2.

An input terminal of the second stage ST2 is connected to the output terminal of the previous stage ST1. Further, the input terminal of the second stage ST2 is connected to the second clock signal line CL2 to which the second clock signal CLK2 is supplied. An output terminal of the second stage ST2 is connected to a 2-1-th gate line GL2-1 disposed in the third pixel line PL3 and a 2-2-th gate line GL2-2 disposed in the fourth pixel line PLA. Therefore, the second stage ST2 outputs the same second gate signal GS2 to pixels P disposed in two adjacent pixel lines PL3 and PL4 through the 2-1-th gate line GL2-1 and the 2-2-th gate line GL2-2.

An input terminal of the third stage ST3 is connected to the output terminal of the previous stage ST2. Further, the input terminal of the third stage ST3 is connected to the third clock signal line CL3 to which the third clock signal CLK3 is supplied. An output terminal of the third stage ST3 is connected to a 3-1-th gate line GL3-1 disposed in the fifth pixel line PL5 and a 3-2-th gate line GL3-2 disposed in the sixth pixel line PL6. Therefore, the third stage ST3 outputs the same third gate signal GS3 to pixels P disposed in two adjacent pixel lines PL5 and PL6 through the 3-1-th gate line GL3-1 and the 3-2-th gate line GL3-2.

An input terminal of the fourth stage ST4 is connected to the output terminal of the previous stage ST3. Further, the input terminal of the fourth stage ST4 is connected to the fourth clock signal line CL4 to which the fourth clock signal CLK4 is supplied. An output terminal of the fourth stage ST4 is connected to a 4-1-th gate line GL4-1 disposed in the seventh pixel line PL7 and a 4-2-th gate line GL4-2 disposed in the eighth pixel line PL8. Therefore, the fourth stage ST4 outputs the same fourth gate signal GS4 to pixels P disposed in two adjacent pixel lines PL7 and PL8 through the 4-1-th gate line GL4-1 and the 4-2-th gate line GL4-2.

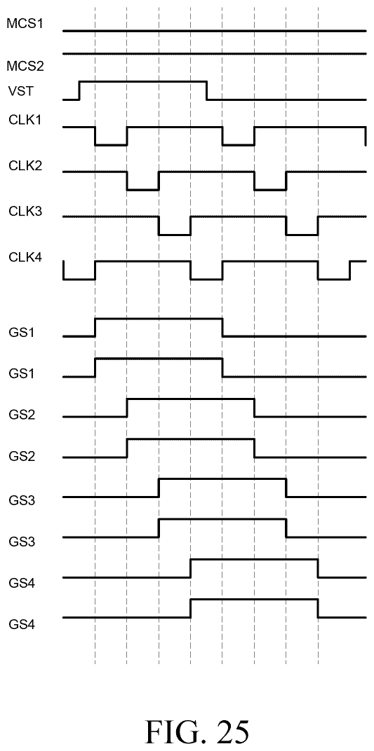

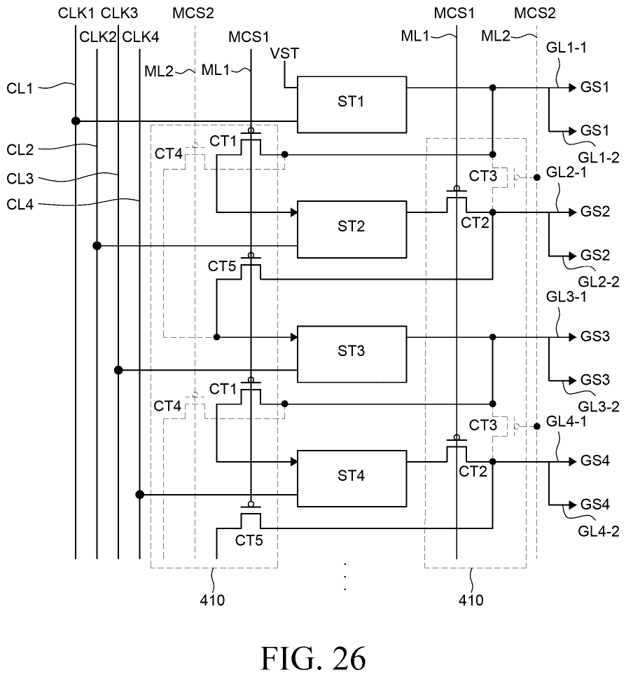

FIG. 25 is a waveform diagram illustrating various signals in a first mode operation of a gate driver of FIG. 24. FIG. 26 is a schematic diagram for explaining a first mode operation of a gate driver of FIG. 24. In FIGS. 25 and 26, an example that the plurality of stages STn is configured by an edge trigger circuit will be described. In FIGS. 25 and 26, an example that the gate driver operates in a first mode will be described.

Referring to FIGS. 25 and 26, a low level of first mode control signal MCS1 which is a turn-on voltage is applied to the first mode control signal line ML1 and a high level of second mode control signal MCS2 which is a turn-off voltage is applied to the second mode control signal line ML2.

In this case, the first control transistor CT1, the second control transistor CT2, and the fifth control transistor CT5 are turned on and the third control transistor CT3 and the fourth control transistor CT4 are turned off.

Therefore, all the plurality of stages ST1 to ST4 is dependently connected so that a gate signal output from a previous stage is input to an input terminal of a next stage. Further, the plurality of stages ST1 to ST4 sequentially outputs gate signals GS1 to GS4 through connected gate lines GL1-1 to GL4-2 according to fall edges of clock signals CLK1 to CLK4 input to each stage ST1 to ST4.

For example, the first gate signal GS1 output from the first stage ST1 is supplied to the 1-1-th gate line GL1-1 and the 1-2-th gate line GL1-2 and is input to an input terminal of the second stage ST2. The second gate signal GS2 output from the second stage ST2 is supplied to a 2-1-th gate line GL2-1 and a 2-2-th gate line GL2-2 and is input to an input terminal of the third stage ST3. The third gate signal GS3 output from the third stage ST3 is supplied to a 3-1-th gate line GL3-1 and a 3-2-th gate line GL3-2 and is input to an input terminal of the fourth stage ST4. The fourth gate signal GS4 output from the fourth stage ST4 is supplied to a 4-1-th gate line GL4-1 and a 4-2-th gate line GL4-2 and is input to an input terminal of the next stage.

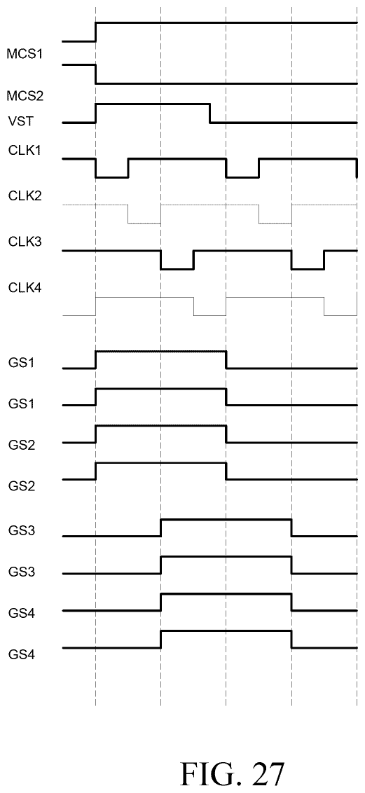

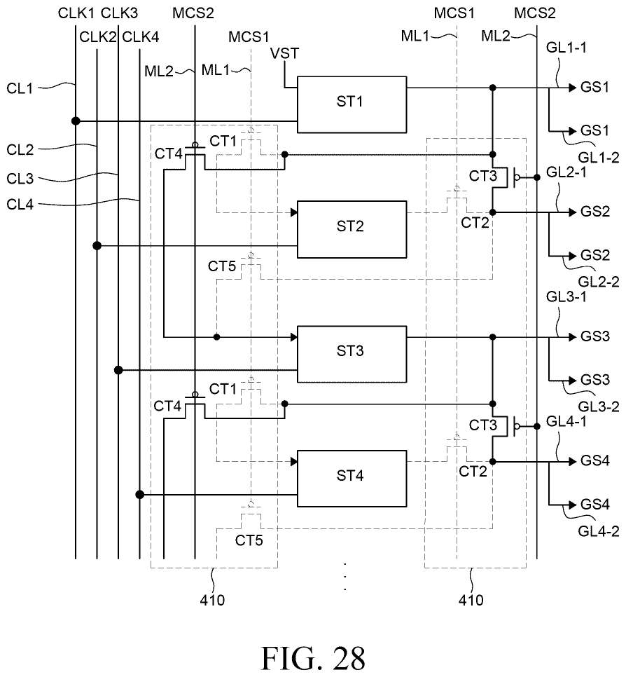

FIG. 27 is a waveform diagram illustrating various signals in a second mode operation of a gate driver of FIG. 24. FIG. 28 is a schematic diagram for explaining a second mode operation of a gate driver of FIG. 24. In FIGS. 27 and 28, an example that the plurality of stages STn is configured by an edge trigger circuit will be described. In FIGS. 27 and 28, an example that the gate driver operates in a second mode will be described.

Referring to FIGS. 27 and 28, a low level of second mode control signal MCS2 which is a turn-on voltage is applied to the second mode control signal line ML2 and a high level of first mode control signal MCS1 which is a turn-off voltage is applied to the first mode control signal line ML1.

In this case, the third control transistor CT3 and the fourth control transistor CT4 are turned on and the first control transistor CT1, the second control transistor CT2, and the fifth control transistor CT5 are turned off.

Therefore, only odd-numbered stages ST1 and ST3 among the plurality of stages ST1 to ST4 are dependently connected so that a gate signal output from a previous stage is input to an input terminal of a next stage. Further, clock signals CLK1 and CLK3 are input to only the odd-numbered stages ST1 and ST3. The odd-numbered stages ST1 and ST3 sequentially output the gate signals GS1 and GS3 through odd-numbered gate lines GL1-1, GL1-2, GL3-1, and GL3-2 and even-numbered gate lines GL2-1, GL2-2, GL4-1, and GL4-2 adjacent to the odd-numbered gate lines GL1-1, GL1-2, GL3-1, and GL3-2 according to falling edge timings of the clock signal CLK1 and CLK3.

For example, the first gate signal GS1 output from the first stage ST1 is supplied to the 1-1-th gate line GL1-1, the 1-2-th gate line GL1-2, the 2-1-th gate line GL2-1, and the 2-2-th gate line GL2-2 and is input to an input terminal of the third stage ST3. The third gate signal GS3 output from the third stage ST3 is supplied to a 3-1-th gate line GL3-1, a 3-2-th gate line GL3-2, a 4-1-th gate line GL4-1, and a 4-2-th gate line GL4-2 and is then input to an input terminal of an odd-numbered stage.

In a display device 2000 according to another example embodiment of the present disclosure, when a partial area of the active area operates with a low resolution, some stages of the gate driver may not operate. Further, when the stage is an edge trigger circuit, some configuration which outputs the clock signal is turned off so as not to supply a clock signal to a stage which does not operate so that the driving IC is driven with a low power to reduce the power consumption.

Further in the display device 2000 according to another example embodiment of the present disclosure, even though the active area is divided to be driven with different resolutions, a driving frequency of the overall active area is not lowered so that only a partial area of the divided active area is changed to a low resolution while operating at a high speed. Further, a high resolution area and a low resolution area can be changed so as to respond to various contents.

In the case of the display device, a data voltage output from the data driver is supplied to a pixel of the display panel to display images so that the larger a resolution and a size of the display panel, the larger the number of pixels. Therefore, there is a problem in that a time to apply a data voltage to each pixel is reduced so that a charging time is reduced.

Accordingly, the display device 2000 according to another example embodiment of the present disclosure includes a first data line DL1 connected to a pixel P disposed in odd-numbered pixel lines PL1 and PL3 and a second data line DL2 connected to a pixel disposed in even-numbered pixel lines PL2 and PL4. Therefore, the first data line DL1 and the second data line DL2 simultaneously supply the data voltage to the pixel P so that a sufficient sampling time of pixels may be ensured even in a high resolution and a high speed operation.

A display device according to the example embodiments of the present disclosure can also be described as follows:

A display device according to an example embodiment of the present disclosure includes a display panel including an active area in which a plurality of pixels is disposed and a non-active area which encloses the active area and a gate driver driven in any one of a first mode or a second mode to supply a gate signal to the plurality of pixels, the gate driver includes a plurality of stages and a mode controller connected between the plurality of stages to control an operation of the gate driver according to a mode control signal.

The gate driver may output the gate signal output from the plurality of stages to gate lines connected to each of the plurality of stages in the first mode and outputs the gate signal output from a 2n-1-th stage, among the plurality of stages, to a gate line connected to the 2n-1-th stage and a gate line connected to a 2n-th stage, among the plurality of stages, in the second mode.

The display device may further include a timing controller which supplies the mode control signal to the mode controller.

The display device may further include a plurality of data lines connected to the plurality of pixels to supply a data voltage and a plurality of gate lines connected to the plurality of stages one to one to supply the gate signal.

The display device may further include a plurality of first data lines which supplies a data voltage to pixels disposed in odd-numbered pixel lines, among the plurality of pixels, a plurality of second data lines which supplies a data voltage to pixels disposed in even-numbered pixel lines, among the plurality of pixels and a first gate line and a second gate line which are connected to the plurality of stages and supply the same gate signal to pixels disposed in two adjacent pixel lines.

The mode control signal may include a first mode control signal and a second mode control signal and the mode controller may include a first control transistor turned on according to the first mode control signal and is connected between an output terminal of a 2n-1-th stage and an input terminal of a 2n-th stage, among the plurality of stages, a second control transistor turned on according to the first mode control signal and is connected to an output terminal of the 2n-th stage, a third control transistor turned on according to the second mode control signal and is connected between an output terminal of a 2n-1-th stage and an output terminal of a 2n-th stage, a fourth control transistor turned on according to the second mode control signal and is connected between an output terminal of a 2n-1-th stage and an input terminal of a 2n+1-th stage and a fifth control transistor turned on according to the first mode control signal and is connected between an output terminal of a 2n-th stage and an input terminal of a 2n+1-th stage.

The active area of the display panel may include a first active area in which a first image is displayed and a second active area in which a second image is displayed and the first active area and the second active area have different resolutions.

The first active area and the second active area may have the same driving frequency.

The gate driver may be disposed in non-active areas on both sides of the active area.

The gate driver may include a plurality of scan drivers and an emission driver.

At least one of the plurality of scan drivers may be configured by an edge trigger circuit and the remaining scan drivers and the emission driver are configured by shift register circuits.

The shift register circuit may include a 1-1-th transistor having a source electrode connected to a line which supplies a start signal, a drain electrode connected to a Q′ node, and a gate electrode connected to a line to which a clock signal of a n-1-th stage is applied, a 1-2-th transistor having a source electrode connected to a line which supplies a gate high voltage, a drain electrode connected to the Q′ node, and a gate electrode connected to a QB node, a 1-3-th transistor having a source electrode connected to the line which supplies the gate high voltage, a drain electrode connected to the QB node, and a gate electrode connected to a line to which a clock signal of a n+2-th stage is applied, a 1-4-th transistor having a source electrode connected to the line which supplies the gate high voltage, a drain electrode connected to the QB node, and a gate electrode connected to a line which supplies the start signal, a 1-5-th transistor having a source electrode connected to the line which supplies the gate high voltage, a drain electrode connected to the QB node, and a gate electrode connected to the Q′ node, a 1-6-th transistor having a source electrode connected to the Q′ node, a drain electrode connected to a Q node, and a gate electrode connected to a line which supplies a gate low voltage, a 1-7-th transistor having a source electrode connected to a line to which a clock signal of an n-th stage is applied, a drain electrode connected to an output terminal, and a gate electrode connected to the Q node, a 1-8-th transistor having a source electrode connected to the line which supplies the gate high voltage, a drain electrode connected to the output terminal, and a gate electrode connected to the QB node, a 1-1-th capacitor having a first electrode connected to the Q node and a second electrode connected to the output terminal and a 1-2-th capacitor having a first electrode connected to the QB node and a second electrode connected to the line which supplies the gate high voltage.

The edge trigger circuit may include a 2-1-th transistor having a source electrode connected to a line which supplies a start signal, a drain electrode connected to a Q′ node, and a gate electrode connected to a line to which a clock signal of a n-th stage is applied, a 2-2-th transistor having a source electrode connected to a line which supplies the gate high voltage, a drain electrode connected to a QC node, and a gate electrode connected to a line which supplies the start signal, a 2-3-th transistor having a source electrode connected to a line to which a clock signal of an n-th stage is applied, a drain electrode connected to the QB node, and a gate electrode connected to the QC node, a 2-4-th transistor having a source electrode connected to the line which supplies the gate high voltage, a drain electrode connected to the QB node, and a gate electrode connected to the Q′ node, a 2-5-th transistor having a source electrode connected to the Q′ node, a drain electrode connected to a Q node, and a gate electrode connected to a line which supplies a gate low voltage, a 2-6-th transistor having a source electrode connected to the line which supplies the gate low voltage, a drain electrode connected to the output terminal, and a gate electrode connected to the Q node, a 2-7-th transistor having a source electrode connected to the line which supplies the gate high voltage, a drain electrode connected to the output terminal, and a gate electrode connected to the QB node, a 2-1-th capacitor having a first electrode connected to a line to which a clock signal of the n-th stage is applied and a second electrode connected to the QC node, a 2-2-th capacitor having a first electrode connected to the Q node and a second electrode connected to the output terminal and a 2-3-th capacitor having a first electrode connected to the QB node and a second electrode connected to the line which supplies the gate high voltage.

A display device according to another example embodiment of the present disclosure includes a display panel and a gate driver which supplies a gate signal to the plurality of pixels, the gate driver includes a plurality of stages and a mode controller connected with the plurality of stages to control the gate driver to be driven in a first mode or a second mode according to a mode control signal, in the first mode, the plurality of stages are connected such that a gate signal output from one stage is input to an input terminal of a next stage, in the second mode, only odd-numbered stages or even-numbered stages among the plurality of stages are connected such that a gate signal output from one stage is input to an input terminal of a next stage.

The mode controller may include a plurality of control transistors connected between the plurality of stages, and the mode controller includes a first mode control signal and a second mode control signal.

The gate driver may include a plurality of scan drivers and an emission driver.

One of the plurality of scan drivers may include an edge trigger circuit and the remaining scan drivers and the emission driver include shift register circuits.

Although the example embodiments of the present disclosure have been described in detail with reference to the accompanying drawings, the present disclosure is not limited thereto and may be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a display panel including an active area in which a plurality of pixels is disposed and a non-active area which encloses the active area; and
a gate driver configured to be driven in a first mode or a second mode to supply a gate signal to the plurality of pixels,
wherein the gate driver includes:
a plurality of stages; and
a mode controller connected between the plurality of stages to control an operation of the gate driver according to a mode control signal.

2. The display device according to claim 1, wherein the gate driver is configured to output the gate signal output from the plurality of stages to gate lines connected to each of the plurality of stages in the first mode and to output the gate signal output from a (2n-1)th stage, among the plurality of stages, to a gate line connected to the (2n-1)th stage and a gate line connected to a (2n)th stage, among the plurality of stages, in the second mode.

3. The display device according to claim 1, further comprising:
a timing controller configured to supply the mode control signal to the mode controller.

4. The display device according to claim 1, further comprising:
a plurality of data lines connected to the plurality of pixels to supply a data voltage; and
a plurality of gate lines connected to the plurality of stages one to one to supply the gate signal.

5. The display device according to claim 1, further comprising:
a plurality of first data lines configured to supply a data voltage to pixels disposed in odd-numbered pixel lines, among the plurality of pixels;
a plurality of second data lines configured to supply a data voltage to pixels disposed in even-numbered pixel lines, among the plurality of pixels; and
a first gate line and a second gate line which are connected to the plurality of stages and supply the same gate signal to pixels disposed in two adjacent pixel lines.

6. The display device according to claim 1, wherein the mode control signal includes a first mode control signal and a second mode control signal and the mode controller includes:
a first control transistor configured to be turned on according to the first mode control signal and is connected between an output terminal of a (2n−1)th stage and an input terminal of a (2n)th stage, among the plurality of stages;
a second control transistor configured to be turned on according to the first mode control signal and is connected to an output terminal of the (2n)th stage;
a third control transistor configured to be turned on according to the second mode control signal and is connected between the output terminal of the (2n−1)th stage and an output terminal of a (2n)th stage;
a fourth control transistor configured to be turned on according to the second mode control signal and is connected between the output terminal of the (2n−1)th stage and an input terminal of a (2n+1)th stage; and
a fifth control transistor configured to be turned on according to the first mode control signal and is connected between the output terminal of the (2n)th stage and the input terminal of a (2n+1)th stage.

7. The display device according to claim 1, wherein the active area of the display panel includes a first active area in which a first image is displayed and a second active area in which a second image is displayed and the first active area and the second active area have different resolutions.

8. The display device according to claim 7, wherein the first active area and the second active area have a same driving frequency.

9. The display device according to claim 1, wherein the gate driver is disposed in non-active areas on both sides of the active area.

10. The display device according to claim 1, wherein the gate driver includes a plurality of scan drivers and an emission driver.

11. The display device according to claim 10, wherein at least one of the plurality of scan drivers includes an edge trigger circuit and the remaining scan drivers and the emission driver include shift register circuits.

12. The display device according to claim 11, wherein the shift register circuit includes:
a (1-1)th transistor having a source electrode connected to a line which supplies a start signal, a drain electrode connected to a Q′ node, and a gate electrode connected to a line to which a clock signal of a (n−1)th stage is applied;
a (1-2)th transistor having a source electrode connected to a line which supplies a gate high voltage, a drain electrode connected to the Q′ node, and a gate electrode connected to a QB node;
a (1-3)th transistor having a source electrode connected to the line which supplies the gate high voltage, a drain electrode connected to the QB node, and a gate electrode connected to a line to which a clock signal of a (n+2)th stage is applied;
a (1-4)th transistor having a source electrode connected to the line which supplies the gate high voltage, a drain electrode connected to the QB node, and a gate electrode connected to a line which supplies the start signal;
a (1-5)th transistor having a source electrode connected to the line which supplies the gate high voltage, a drain electrode connected to the QB node, and a gate electrode connected to the Q′ node;
a (1-6)th transistor having a source electrode connected to the Q′ node, a drain electrode connected to a Q node, and a gate electrode connected to a line which supplies a gate low voltage;
a (1-7)th transistor having a source electrode connected to a line to which a clock signal of an n-th stage is applied, a drain electrode connected to an output terminal, and a gate electrode connected to the Q node;
a (1-8)th transistor having a source electrode connected to the line which supplies the gate high voltage, a drain electrode connected to the output terminal, and a gate electrode connected to the QB node;
a (1-1)th capacitor having a first electrode connected to the Q node and a second electrode connected to the output terminal; and
a (1-2)th capacitor having a first electrode connected to the QB node and a second electrode connected to the line which supplies the gate high voltage.

13. The display device according to claim 11, wherein the edge trigger circuit includes:
a (2-1)th transistor having a source electrode connected to a line which supplies a start signal, a drain electrode connected to a Q′ node, and a gate electrode connected to a line to which a clock signal of a nth stage is applied;
a (2-2)th transistor having a source electrode connected to a line which supplies the gate high voltage, a drain electrode connected to a QC node, and a gate electrode connected to a line which supplies the start signal;
a (2-3)th transistor having a source electrode connected to a line to which a clock signal of an n-th stage is applied, a drain electrode connected to the QB node, and a gate electrode connected to the QC node;
a (2-4)th transistor having a source electrode connected to the line which supplies the gate high voltage, a drain electrode connected to the QB node, and a gate electrode connected to the Q′ node;
a (2-5)th transistor having a source electrode connected to the Q′ node, a drain electrode connected to a Q node, and a gate electrode connected to a line which supplies a gate low voltage;
a (2-6)th transistor having a source electrode connected to the line which supplies the gate low voltage, a drain electrode connected to an output terminal, and a gate electrode connected to the Q node;
a (2-7)th transistor having a source electrode connected to the line which supplies the gate high voltage, a drain electrode connected to the output terminal, and a gate electrode connected to the QB node;
a (2-1)th capacitor having a first electrode connected to a line to which a clock signal of the n-th stage is applied and a second electrode connected to the QC node;
a (2-2)th capacitor having a first electrode connected to the Q node and a second electrode connected to the output terminal; and
a (2-3)th capacitor having a first electrode connected to the QB node and a second electrode connected to the line which supplies the gate high voltage.

14. A display device, comprising:
a display panel; and
a gate driver which supplies a gate signal to the plurality of pixels,
wherein the gate driver includes:
a plurality of stages; and
a mode controller connected with the plurality of stages to control the gate driver to be driven in a first mode or a second mode according to a mode control signal,
wherein, in the first mode, the plurality of stages are connected such that a gate signal output from one stage is input to an input terminal of a next stage,
wherein, in the second mode, only odd-numbered stages or even-numbered stages among the plurality of stages are connected such that a gate signal output from one stage is input to an input terminal of a next stage.

15. The display device according to claim 14, wherein the mode controller includes a plurality of control transistors connected between the plurality of stages, and
wherein the mode controller includes a first mode control signal and a second mode control signal.

16. The display device according to claim 14, wherein the gate driver includes a plurality of scan drivers and an emission driver.

17. The display device according to claim 16, wherein one of the plurality of scan drivers includes an edge trigger circuit and the remaining scan drivers and the emission driver include shift register circuits.
